(19) United States
(12) Patent Application Publication
(10) Pub. No.: US 2024/0421132 A1
(43) Pub. Date: Dec. 19, 2024

(54) SEMICONDUCTOR DEVICE

(71) Applicant: DENSO CORPORATION, Kariya-city (JP)

(72) Inventors: Shingo TSUCHIMOCHI, Kariya-city (JP); Takanori KAWASHIMA, Kariya-city (JP)

(21) Appl. No.: 18/817,993

(22) Filed: Aug. 28, 2024

Related U.S. Application Data
(63) Continuation of application No. PCT/JP2023/004587, filed on Feb. 10, 2023.

(30) Foreign Application Priority Data
Mar. 2, 2022 (JP) 2022-032148

(51) Int. Cl. H01L 25/07; H01L 23/00; H01L 23/31; H01L 23/495

(52) U.S. Cl. CPC H01L 25/072; H01L 23/3121; H01L 23/49562; H01L 24/32; H01L 24/48; H01L 2224/32227; H01L 2224/48175; H01L 2924/13091; H01L 2924/3512

(57) ABSTRACT

A semiconductor device includes a semiconductor element, a substrate, a bonding material, a main terminal and a plating film. The substrate has an insulating base member, a front surface metal body on a front surface of the insulating base member and electrically connected to a main electrode of the semiconductor element, and a back surface metal body on a back surface of the insulating base member. The bonding material is interposed between the main electrode and the front surface metal body. The main terminal has a solid-state bonded portion bonded to the front surface metal body. The plating film is disposed on the front surface metal body and the main terminal to cover the solid-state bonded portion. The main terminal includes a wide terminal having one solid-state bonded portion and having an overlapping region a width of which is greater than the solid-state bonded portion.

### CROSS REFERENCE TO RELATED APPLICATIONS

The present application is a continuation application of International Patent Application No. PCT/JP2023/004587 filed on Feb. 10, 2023, which designated the U.S. and claims the benefit of priority from Japanese Patent Application No. 2022-032148 filed on Mar. 2, 2022. The entire disclosures of all of the above applications are incorporated herein by reference.

### TECHNICAL FIELD

The present disclosure relates to a semiconductor device.

### BACKGROUND

JP2014-60410A discloses a semiconductor device. The semiconductor device includes a substrate (insulating substrate), a semiconductor element having main electrodes on both sides, and a main terminal (terminal for external connection). One of the main electrodes of the semiconductor element is connected to a front surface metal body (metal foil) of the substrate via a solder layer. The main terminal is connected to the front surface metal body by ultrasonic bonding or the like. The disclosure of JP2014-60410A is incorporated herein by reference as an explanation of technical elements in the present disclosure.

### SUMMARY

The present disclosure describes a semiconductor device. According to an aspect, the semiconductor device includes a semiconductor element, a substrate, a bonding material, a main terminal, and a plating film. The semiconductor element has a first main electrode on a first surface and a second main electrode on a second surface opposite to the first surface in a thickness direction. The substrate has an insulating base member, a front surface metal body disposed on a front surface of the insulating base member and electrically connected to the first main electrode, and a back surface metal body disposed on a back surface of the insulating base member opposite to the front surface of the insulating base member. The bonding material is interposed between the first main electrode and the front surface metal body to bond the first main electrode and the front surface metal body. The main terminal has a solid-state bonded portion bonded to the front surface metal body. The plating film is disposed on the front surface metal body and the main terminal so as to cover the solid-state bonded portion. The main terminal includes a wide terminal that has one solid-state bonded portion bonded to the front surface metal body and includes an overlapping region overlapping with the front surface metal body in the thickness direction, the overlapping region including a bonded region providing the solid-state bonded portion bonded to the front surface metal body and a non-bonded region other than the bonded region in the overlapping region and being adjacent to the bonded region at least in a width direction of the main terminal, so that a width of the overlapping region is greater than a width of the solid-state bonded portion in the width direction.

### BRIEF DESCRIPTION OF DRAWINGS

Features and advantages of the present disclosure will become more apparent from the following detailed description made with reference to the accompanying drawings, in which:

FIG. 1 is a diagram illustrating a circuit configuration of a power conversion device to which a semiconductor device according to a first embodiment is applied;

FIG. 2 is a perspective view illustrating the semiconductor device;

FIG. 3 is a plan view illustrating the semiconductor device;

FIG. 4 is a plan view illustrating a substrate on a drain electrode side;

FIG. 5 is a plan view illustrating a substrate on a source electrode side;

FIG. 6 is a cross-sectional view taken along a line VI-VI in FIG. 3;

FIG. 7 is a cross-sectional view taken along a line VII-VII in FIG. 3;

FIG. 8 is a perspective view illustrating a state in which the substrate on the drain electrode side and a lead frame are bonded to each other;

FIG. 9 is a plan view illustrating a connection structure between the substrate on the drain electrode side and a main terminal;

FIG. 10 is an enlarged view of a region X shown in FIG. 9;

FIG. 11 is a cross-sectional view taken along a line XI-XI in FIG. 10;

FIG. 12 is a plan view illustrating a modification;

FIG. 13 is a plan view illustrating a modification;

FIG. 14 is a plan view illustrating a modification;

FIG. 15 is a plan view illustrating a modification;

FIG. 16 is a cross-sectional view illustrating a reference example;

FIG. 17 is a cross-sectional view illustrating a reference example;

FIG. 18 is a cross-sectional view illustrating a reference example;

FIG. 19 is an enlarged perspective view of a part of a semiconductor device according to a second embodiment, the part including a bonded portion between a main terminal and a front surface metal body;

FIG. 20 is a cross-sectional view taken along a line XX-XX in FIG. 19;

FIG. 21 is a diagram including cross-sectional views for illustrating a process of an ultrasonic bonding;

FIG. 22 is a cross-sectional view illustrating an ultrasonic bonding between a main terminal and a front surface metal body in a manufacturing method of a semiconductor device according to a third embodiment;

FIG. 23 is a cross-sectional view illustrating an example of a semiconductor device;

FIG. 24 is a cross-sectional view illustrating a modification;

FIG. 25 is a cross-sectional view of a part of a semiconductor device according to a fourth embodiment, the part including a bonded portion between a main terminal and a front surface metal body;

FIG. 26 is a cross-sectional view illustrating a part of a semiconductor device according to a fifth embodiment, the part including a separation portion of a back surface metal body; and

FIG. 27 is a plan view illustrating an example of a pattern of the back surface metal body.

### DETAILED DESCRIPTION

For example, a semiconductor device includes a substrate, a semiconductor element having main electrodes on both sides, and a main terminal. One of the main electrodes of the semiconductor element is connected to a front surface metal body of the substrate via a solder layer, and the main terminal is connected to the front surface metal body of the substrate by ultrasonic bonding or the like. In a configuration in which the main terminal is bonded to the substrate, there is a fear that the durable life of the main terminal may be reduced due to electric field concentration near the bonded portion. Also, taking into consideration the wettability of the solder layer and the bondability of the main terminal, it is conceivable to apply a plating film after bonding the main terminal to the front surface metal body. In such a case, if a plating solution residue occurs, there is a fear that the plating solution will seep out in a later process, causing a decrease in the wettability of the solder layer. From the above-described viewpoint or from other viewpoints not mentioned, further improvement is required for semiconductor devices.

The present disclosure provides a semiconductor device capable of improving the durable life of a main terminal while suppressing a defect caused by a residual plating solution.

According to an aspect of the present disclosure, a semiconductor device includes a semiconductor element, a substrate, a bonding material, a main terminal, and a plating film. The semiconductor element has a first main electrode on a first surface and a second main electrode on a second surface opposite to the first surface in a thickness direction of the semiconductor element. The substrate has an insulating base member, a front surface metal body disposed on a front surface of the insulating base member and electrically connected to the first main electrode, and a back surface metal body disposed on a back surface of the insulating base member opposite to the front surface in the thickness direction. The bonding material is interposed between the first main electrode and the front surface metal body to bond the first main electrode and the front surface metal body. The main terminal has a solid-state bonded portion bonded to the front surface metal body. The plating film is disposed on the front surface metal body and the main terminal so as to cover the solid-state bonded portion. The main terminal includes a wide terminal that has one solid-state bonded portion with the front surface metal body and includes an overlapping region overlapping with the front surface metal body in the thickness direction. The overlapping region includes a bonded region providing the solid-state bonded portion bonded to the front surface metal body and a non-bonded region other than the bonded region and adjacent to the bonded region in a width direction of the main terminal, so that a width of the overlapping region is greater than a width of the solid-state bonded portion in the width direction.

In the semiconductor device described above, the main terminal includes the wide terminal. The wide terminal has the non-bonded region. The non-bonded region is adjacent to the bonded region at least in the width direction. With this configuration, the width of the overlapping region is greater than the width of the solid-state bonded portion. Therefore, the electric field concentration is suppressed, and ultimately the durable life of the main terminal (wide terminal) can be improved.

The plating film is provided so as to cover the solid-state bonded portion. That is, the plating film is formed after solid-state bonding. However, in the wide terminal, the number of the solid-state bonded portion with the front surface meal body is one. The non-bonded region is laterally open. Therefore, even if the plating solution enters between the non-bonded region and the front surface metal body, the plating solution is easily discharged. The plating solution is less likely to remain between the non-bonded region and the front surface metal body. Therefore, the occurrence of plating solution residue can be suppressed. By suppressing the plating solution residue, it is possible to suppress a decrease in the reliability of connection between, for example, the semiconductor element and the front surface metal body. Accordingly, the defect caused by the plating solution residue can be suppressed.

Hereinafter, embodiments of the present disclosure will be described with reference to the drawings. The same or corresponding elements are designated with the same reference numerals throughout the embodiments, and descriptions thereof will not be repeated. When only part of the configuration is described in each embodiment, the configuration of the other preceding embodiments can be applied to other parts of the configuration. Further, not only the combinations of the configurations explicitly shown in the description of the respective embodiments, but also the configurations of the plurality of embodiments can be partially combined even when they are not explicitly shown as long as there is no difficulty in the combination in particular.

The semiconductor device according to the present embodiment is applicable to, for example, a power conversion device for a moving object with a rotary electric machine as a drive source. Examples of mobile objects include electric vehicles such as battery electric vehicles (BEVs), hybrid electric vehicles (HEVs), and plug-in hybrid electric vehicles (PHEVs), flying objects such as electric vertical take-off and landing aircraft and drones, ships, construction machinery, and agricultural machinery. Hereinafter, examples applied to a vehicle will be described.

### First Embodiment

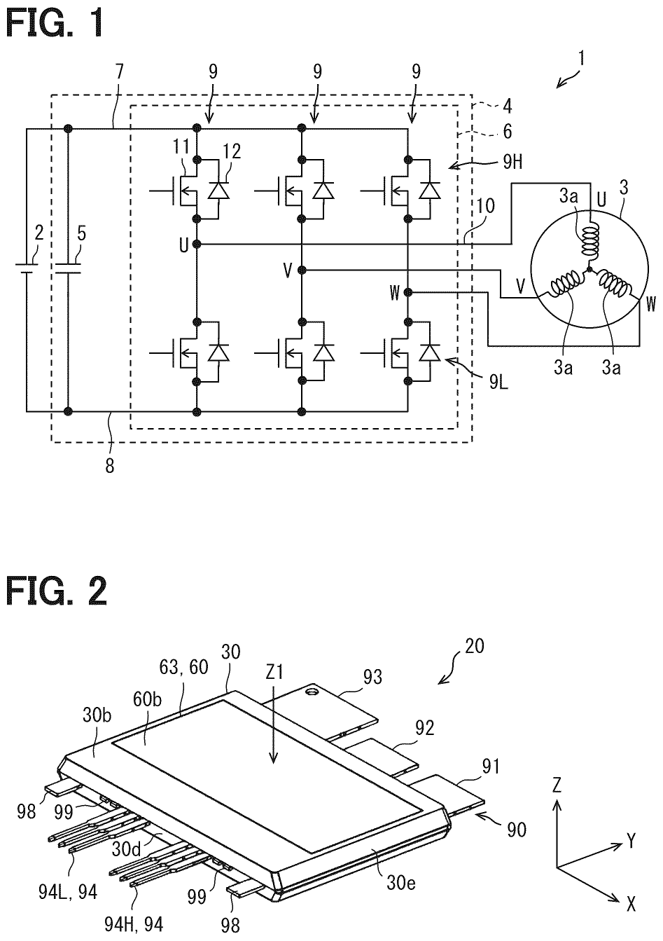

First, a schematic configuration of a drive system 1 of a vehicle will be described with reference to FIG. 1.

### Vehicle Drive System

As shown in FIG. 1, a vehicle drive system 1 is provided with a direct current (DC) power supply 2, a motor generator 3, and a power conversion device 4.

The DC power supply 2 is a direct-current voltage source including a chargeable/dischargeable secondary battery. Examples of the secondary battery include a lithium ion battery and a nickel hydride battery. The motor generator 3 is a three-phase alternating current (AC) type rotary electric machine. The motor generator 3 functions as a vehicle driving power source, that is, an electric motor. The motor generator 3 functions also as a generator during regeneration. The power conversion device 4 performs electric power conversion between the DC power supply 2 and the motor generator 3.

### Power Conversion Device

Next, a circuit configuration of the power conversion device 4 will be described with reference to FIG. 1. The power conversion device 4 includes a power conversion circuit. The power conversion device 4 according to the present embodiment includes a smoothing capacitor 5 and an inverter 6 as the power conversion circuit.

The smoothing capacitor 5 mainly smoothes the DC voltage supplied from the DC power supply 2. The smoothing capacitor 5 is connected between a P line 7 which is a power line on a high potential side and an N line 8 which is a power line on a low potential side. The P line 7 is connected to a positive electrode of the DC power supply 2, and the N line 8 is connected to a negative electrode of the DC power supply 2. The positive electrode of the smoothing capacitor 5 is connected to the P line 7 at a position between the DC power supply 2 and the inverter 6. The negative electrode of the smoothing capacitor 5 is connected to the N line 8 at a position between the DC power supply 2 and the inverter 6. The smoothing capacitor 5 is connected to the DC supply 2 in parallel.

The inverter 6 corresponds to a DC-AC converter circuit. The inverter 6 converts the DC voltage into a three-phase AC voltage according to the switching control by the control circuit (not shown) and outputs the three-phase AC voltage to the motor generator 3. Thereby, the motor generator 3 is driven to generate a predetermined torque. At the time of regenerative braking of the vehicle, the inverter 6 converts the three-phase AC voltage generated by the motor generator 3 by receiving the rotational force from wheels into the DC voltage according to the switching control by the control circuit, and outputs the DC voltage to the P line 7. In this way, the inverter 6 performs bidirectional power conversion between the DC power supply 2 and the motor generator 3.

The inverter 6 includes upper-lower arm circuits 9 for three phases. The upper-lower arm circuit 9 will be also referred to as a “leg”. Each of the upper-lower arm circuits 9 has an upper arm 9H and a lower arm 9L. The upper arm 9H and the lower arm 9L are connected in series between the P line 7 and the N line 8 with the upper arm 9H being connected to the P line 7. A connection point between the upper arm 9H and the lower arm 9L is connected to a winding 3a of a corresponding phase in the motor generator 3 via an output line 10. The inverter 6 has six arms. Each of the arms is configured to include a switching element. At least a portion of each of the P line 7, the N line 8, and the output line 10 is made of a conductive member such as a bus bar.

In the present embodiment, an n-channel MOSFET 11 is used as the switching element that constitutes each arm. The number of switching elements constituting each arm is not particularly limited. The number thereof may be one or more. MOSFET is an abbreviation for Metal Oxide Semiconductor Field Effect Transistor.

In the present embodiment, as an example, each arm has one MOSFET 11. In the upper arm 9H, a drain of the MOSFET 11 is connected to the P line 7. In the lower arm 9L, a source of the MOSFET 11 is connected to the N line 8. The source of the MOSFET 11 in the upper arm 9H and the drain of the MOSFET 11 in the lower arm 9L are connected to each other.

A freewheeling diode 12 is connected in anti-parallel to each of the MOSFETs 11. The diode 12 may be a parasitic diode (body diode) of the MOSFET 11, or may be provided separately from the parasitic diode. An anode of the diode 12 is connected to the source of the corresponding MOSFET 11, and a cathode of the diode 12 is connected to the drain of the corresponding MOSFET 11.

The switching element is not limited to the MOSFET 11. For example, the switching element may be an IGBT. IGBT is an abbreviation for Insulated Gate Bipolar Transistor. A freewheeling diode is also connected in anti-parallel to the IGBT.

The power conversion device 4 may further include a converter as a power conversion circuit. The converter is a DC-DC converter circuit for converting the DC voltage to a DC voltage with different value. The converter is disposed between the DC power supply 2 and the smoothing capacitor 5. The converter is configured to include, for example, a reactor and the upper-lower arm circuits 9 described above. This configuration can boost and suppress the voltage. The power conversion device 4 may further include a filter capacitor for removing power supply noise from the DC power supply 2. The filter capacitor is provided between the DC power supply 2 and the converter.

The power conversion device 4 may include a drive circuit for the switching elements constituting the inverter 6 and the like. The drive circuit supplies a drive voltage to the gate of the MOSFET 11 of the corresponding arm based on a drive command of the control circuit. The drive circuit drives the corresponding MOSFET 11, that is, turns on and off the corresponding MOSFET 11 by application of the drive voltage. The drive circuit may be referred to as a “driver”.

The power conversion device 4 may include a control circuit for the switching element. The control circuit generates a drive command for operating the MOSFET 11 and outputs the drive command to the drive circuit. The control circuit generates the drive command based on a torque request input from a host ECU (not illustrated) and signals detected by various sensors. ECU is an abbreviation for Electronic Control Unit.

Various sensors include, for example, a current sensor, a rotation angle sensor, and a voltage sensor. The current sensor detects a phase current flowing through the winding 3a of each phase. The rotation angle sensor detects a rotation angle of a rotor of the motor generator 3. The voltage sensor detects a voltage across the smoothing capacitor 5. The control circuit outputs, for example, a PWM signal as the drive command. The control circuit includes, for example, a processor and a memory. PWM is an abbreviation for Pulse Width Modulation.

### Semiconductor Device

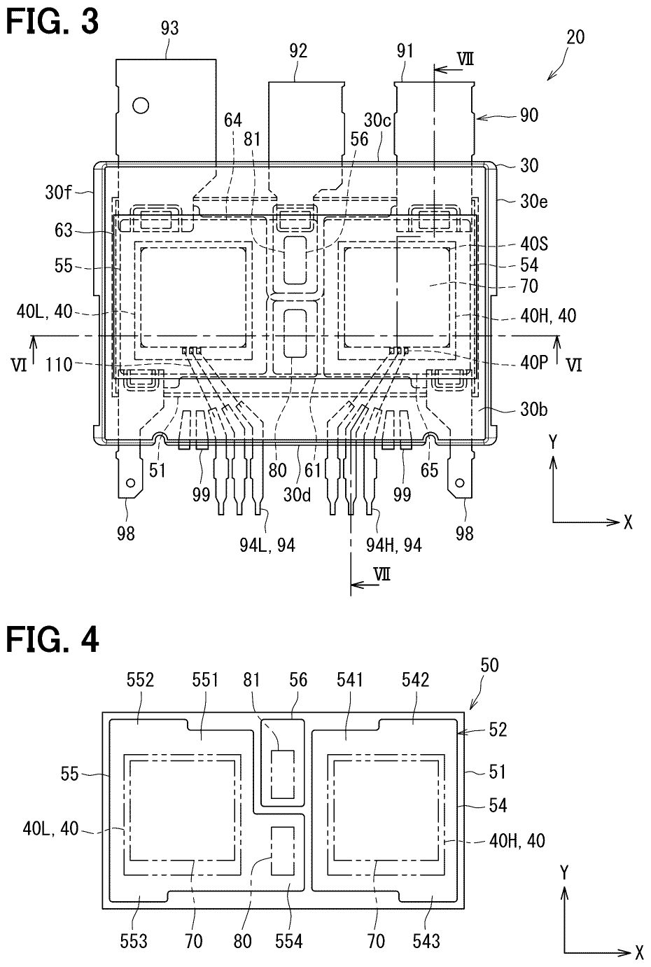

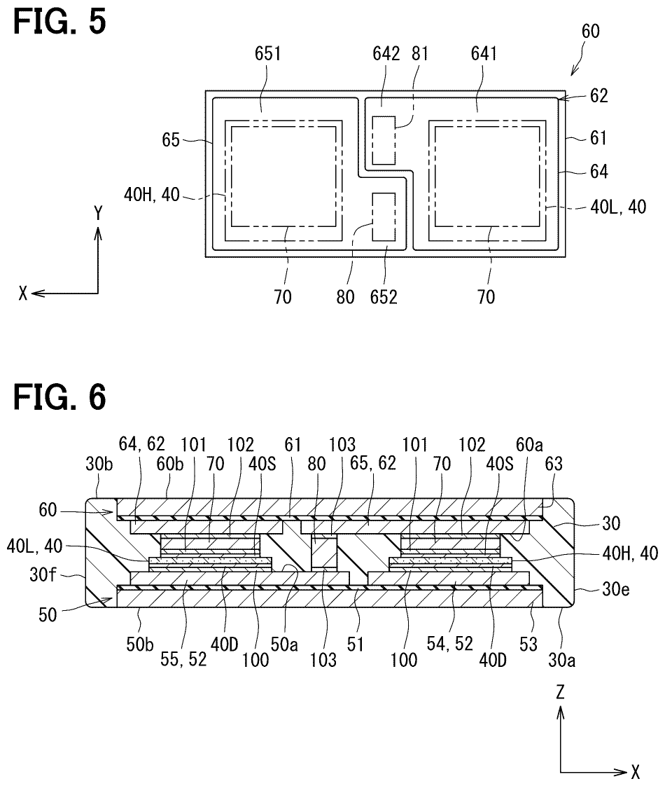

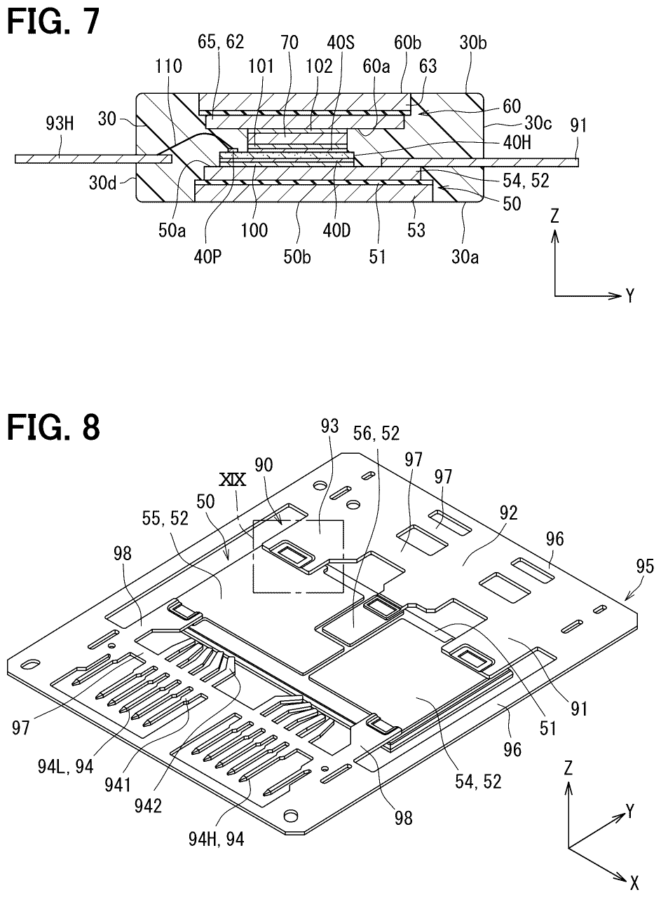

Next, the schematic configuration of the semiconductor device will be described with reference to FIGS. 2 to 8. FIG. 2 is a perspective view illustrating a semiconductor device. FIG. 3 is a plan view illustrating the semiconductor device when viewed along a direction Z1 in FIG. 2. In FIG. 3, the elements covered by a sealing body are illustrated with dashed lines. FIG. 4 is a plan view illustrating a substrate on a drain electrode side. FIG. 5 is a plan view illustrating a substrate on a source electrode side. FIGS. 4 and 5 show patterns of a front surface metal body. In FIGS. 4 and 5, a semiconductor element, a conductive spacer, a substrate connection portion are indicated by two-dot chain lines in order to show their positional relationship with the front surface metal body. FIG. 6 is a cross-sectional view taken along a line VI-VI in FIG. 3. FIG. 7 is a cross-sectional view taken along a line VII-VII in FIG. 3. FIG. 8 is a perspective view illustrating a state in which a lead frame is bonded to the substrate on the drain electrode side.

In the following description, the thickness direction of the semiconductor element (semiconductor substrate) is defined as a Z direction, and the arrangement direction of the semiconductor elements is defined as an X direction. The direction perpendicular to both the Z direction and the Y direction is defined as a Y direction. Unless otherwise specified, a shape of an element viewed along the Z direction, that is, a shape of an element along an XY plane defined by the X-direction and Y-direction is referred to as a planar shape or a shape in a plan view.

A semiconductor device 20 shown in FIGS. 2 and 3 constitutes one of the upper-lower arm circuit 9, that is, the upper-lower arm circuit 9 for one phase. The semiconductor device 20 includes a sealing body 30, a semiconductor element 40, substrates 50 and 60, a conductive spacer 70, substrate connection portions 80 and 81, and an external connection terminal 90.

The sealing body 30 seals part of other elements constituting the semiconductor device 20. The rest of the other elements are exposed to the outside of the sealing body 30. The sealing body 30 is, for example, made of a resin. An example of the resin is epoxy resin. The sealing body 30 is molded by, for example, a transfer molding method using a resin as the material. Such a sealing body 30 may be called a sealing resin body, a molded resin, a resin molded body, or the like. The sealing body 30 may be made using, for example, gel. The gel is filled (disposed) in, for example, a facing region of the pair of substrates 50 and 60.

As illustrated in FIGS. 2 and 3, the sealing body 30 has a substantially rectangular shape in a plan view. The sealing body 30 has, as surfaces forming an outer contour, a first surface 30a and a second surface 30b opposite to the first surface 30a in the Z direction. The first surface 30a and the second surface 30b are, for example, flat surfaces. The sealing body 30 also has side surfaces 30c, 30d, 30e, and 30f as surfaces connecting between the first surface 30a and the second surface 30b. The side surface 30c is a surface from which main terminals 91, 92, and 93 of the external connection terminal 90 project. The side surface 30d is the surface opposite to the side surface 30c in the Y direction. The side surface 30d is the surface from which signal terminals 94 project. The side surfaces 30e and 30f are surfaces from which the external connection terminal 90 does not project. The side surface 30e is the surface opposite to the side surface 30f in the X direction.

The semiconductor element 40 includes a switching element formed on a semiconductor substrate that is made of a material such as silicon (Si), a wide bandgap semiconductor having a wider bandgap than silicon, or the like. Examples of the wide bandgap semiconductor include silicon carbide (SiC), gallium nitride (GaN), gallium oxide (Ga₂O₃) and diamond. The semiconductor element 40 may be referred to as a power element or a semiconductor chip.

The semiconductor device 40 of the present embodiment is configured to include the n-channel MOSFET 11 described above formed on a SiC semiconductor substrate. The MOSFET 11 has a vertical structure such that a main current flows in the thickness direction of the semiconductor element 40 (semiconductor substrate), that is, in the Z direction. The semiconductor element 40 has main electrodes of the switching element on both sides in the Z direction, which is the thickness direction of the semiconductor element 40 itself. Specifically, the semiconductor element 40 has, as the main electrodes, a drain electrode 40D on a first surface and a source electrode 40S on a second surface opposite to the first surface in the Z direction. The main current flows between the drain electrode 40D and the source electrode 40S.

In a case where the diode 12 is provided by a parasitic diode, the source electrode 40S also serves as the anode electrode, and the drain electrode 40D also serves as the cathode electrode. The diode 12 may be formed on a chip separate from the MOSFET 11. The drain electrode 40D is a main electrode on the high potential side, and the source electrode 40S is a main electrode on the low potential side.

The semiconductor element 40 has a substantially rectangular shape, for example a substantially square shape, in a plan view. As shown in FIGS. 3 and 7, the semiconductor element 40 has a pad 40P, which is a signal electrode, on the second surface. The pad 40P is disposed on the second surface of the semiconductor element 40 at a position different from the position of the source electrode 40S. The pad 40P includes at least a gate pad. In the present embodiment, the semiconductor element 40 has three pads 40P. Examples of the pads 40P include a gate pad, a Kelvin source pad, and a current sensing pad. The gate pad is a pad 40P used for applying the drive voltage to the gate electrode of the MOSFET 11. The Kelvin source pad is a pad 40P for detecting the source potential of the MOSFET 11, that is, the potential of the source electrode 40S. The current sensing pad 40P is for detecting a sense current proportional to the main current, and thus detecting the main current.

The semiconductor element 40 includes a semiconductor element 40H constituting the upper arm 9H and a semiconductor element 40L constituting the lower arm 9L. The semiconductor elements 40H and 40L have a similar configuration. As an example, the number of each of the semiconductor elements 40H and 40L is one. As shown in FIG. 3 and other figures, the semiconductor elements 40H and 40L are aligned in the X direction. The semiconductor elements 40 are disposed at approximately the same positions as each other in the Z direction. The drain electrode 40D of each of the semiconductor elements 40 faces the substrate 50. The source electrode 40S of each semiconductor element 40 faces the substrate 60.

The substrates 50 and 60 are disposed in the Z direction so as to interpose the semiconductor element 40 therebetween. The substrates 50 and 60 are disposed so that at least parts thereof face each other in the Z direction. The substrates 50 and 60 enclose the entire semiconductor elements 40 (40H and 40L) in a plan view.

The substrate 50 is disposed adjacent to the drain electrode 40D of the semiconductor element 40. The substrate 60 is disposed adjacent to the source electrode 40S of the semiconductor element 40. The substrate 50 is electrically connected to the drain electrode 40D as described below, and provides a wiring function. Similarly, the substrate 60 is electrically connected to the source electrode 40S and provides a wiring function. For this reason, the substrates 50 and 60 may also be referred to as wiring members, wiring substrates, and the like. The substrate 50 may also be referred to as a drain substrate, and the substrate 60 may also be referred to as a source substrate. The substrates 50 and 60 each provide a heat dissipation function for dissipating heat generated from the semiconductor element 40. For this reason, the substrates 50 and 60 may also be referred to as heat dissipation members.

The substrate 50 has a facing surface 50a facing the semiconductor element 40 and a back surface 50b on an opposite to the facing surface 50a. The substrate 50 includes an insulating base member 51, a front surface metal body 52, and a back surface metal body 53. The substrate 60 has a facing surface 60a facing the semiconductor element 40 and a back surface 60b on an opposite side to the facing surface 60a. The substrate 60 includes an insulating base member 61, a front surface metal body 62, and a back surface metal body 63. In the following description, the front surface metal bodies 52 and 62 and the back surface metal bodies 53 and 63 may be simply referred to as metal bodies 52, 53, 62 and 63. In the substrate 50, the insulating base member 51 and the metal bodies 52 and 53 are stacked on top of each other. In the substrate 60, the insulating base member 61 and the metal bodies 62 and 63 are stacked on top of each other.

The insulating base member 51 electrically separates the front surface metal body 52 and the back surface metal body 53. Similarly, the insulating base member 61 electrically separates the front surface metal body 62 and the back surface metal body 63. The insulating base members 51 and 61 may be referred to as insulating layers. The material of the insulating base members 51 and 61 is resin, or ceramic as an inorganic material. As the resin, for example, an epoxy-based resin or a polyimide-based resin can be used. As the ceramic, for example, Al₂O₃ (alumina), Si₃N₄ (silicon nitride) or the like can be used. When the insulating base members 51 and 61 include the resin, the substrates 50 and 60 may be referred to as metal-resin substrates. When the insulating base members 51 and 61 include the ceramic, the substrates 50 and 60 may be referred to as metal-ceramic substrates.

In the case of the resin-based insulating base members 51 and 61, the thickness of each of the insulating base members 51 and 61, that is, the length in the Z direction, is preferably about 50 μm to 300 μm considering the heat dissipation and the electrical insulation. In the case of the ceramic-based insulating resin members 51 and 61, the thickness of each of the insulating base members 51 and 61 is preferably about 200 μm to 500 μm. In the Z direction, the front surfaces of the insulating base members 51 and 61 are inner surfaces, that is, surfaces facing the semiconductor element 40, and the back surfaces of the insulating base members 51 and 61 are outer surfaces and on opposite sides to the front surfaces in the Z direction. The material configurations of the insulating base members 51 and 61 may be common (same) to or different from each other. In the present embodiment, the insulating base members 51 and 61 are made of the same material.

The metal bodies 52, 53, 62 and 63 are provided, for example, as metal plates or metal foils. The metal bodies 52, 53, 62, and 63 are each made of a metal material having favorable electrical and thermal conductivity, such as copper (Cu). The thickness of each of the metal bodies 52, 53, 62, and 63 is, for example, about 0.1 mm to 3 mm. The front surface metal body 52 is disposed on the front surface of the insulating base member 51 in the Z direction. The back surface metal body 53 is disposed on the back surface of the insulating base member 51. Similarly, the front surface metal body 62 is disposed on the front surface of the insulating base member 61 in the Z direction. The back surface metal body 63 is disposed on the back face of the insulating base member 61.

The relationship in thickness between the front surface metal bodies 52 and 62 and the back surface metal bodies 53 and 63 is not particularly limited. The thickness of the front surface metal body 52 may be greater than that of the back surface metal body 53 or may be substantially equal to that of the back surface metal body 53. The thickness of the front surface metal body 52 may be smaller than that of the back surface metal body 53. Similarly, the thickness of the front surface metal body 62 may be greater than the back surface metal body 63 or may be substantially equal to that of the back surface metal body 63. The thickness of the front surface metal body 62 may be smaller than that of the back surface metal body 63. The relationship in thickness between the front surface metal bodies 52 and 62 is not particularly limited, and the relationship in thickness between the back surface metal bodies 53 and 63 is not particularly limited.

The front surface metal bodies 52 and 62 are patterned. The front surface metal bodies 52 and 62 provide wiring lines, that is, circuits. For this reason, the front surface metal bodies 52 and 62 are also referred to as circuit patterns, wiring layers, circuit conductors, and the like. The surface of the front surface metal body 52 and a non-arrangement area of the surface of the insulating base member 51 where the front surface metal body 52 is not arranged form the facing surface 50a of the substrate 50. Similarly, the surface of the front surface metal body 62 and a non-arrangement area of the surface of the insulating base member 61 where the front surface metal body 62 is not arranged form the facing surface 60a of the substrate 60.

For example, the substrates 50 and 60 may be each formed by the following procedure: the front surface metal body 52, 62 patterned into a predetermined shape by pressing, etching, or the like is prepared; and then the front surface metal body 52, 62 prepared is brought into close contact with a two-layer stacked body made of the insulating base member 51, 61 and the back surface metal body 53, 63. Alternatively, after the three-layer stacked body made of the front surface metal body 52, 62, the insulating base member 51, 61, and the back surface metal body 53, 63 is formed, the front surface metal body 52, 62 may be patterned by cutting or etching.

As shown in FIGS. 3, 4, 6, and 7, the front surface metal body 52 has a P wiring 54, a relay wiring 55, and an N wiring 56. The P wiring 54, the relay wiring 55, and the N wiring 56 are electrically separated from one another by a predetermined interval (gap). The gap is filled with the sealing body 30.

The P wiring 54 is connected to the main terminal 91 and the drain electrode 40D of the semiconductor element 40H. The P wiring 54 electrically connects the main terminal 91 and the drain electrode 40D of the semiconductor element 40H. As an example, the P wiring 54 has a base portion 541 and extension portions 542 and 543. The base portion 541 encloses the semiconductor element 40H in a plan view. The base portion 541 has a generally rectangular shape in the plan view with the Y direction as the longitudinal direction.

The extension portions 542 and 543 extend from the base portion 541 in the Y direction. The length in the X direction of each of the extension portions 542 and 543, that is, the width, is narrower than the width of the base portion 541. The extension portions 542 and 543 each provide at least a portion of the area to which the lead frame elements including the external connection terminals 90 are connected. The extension portion 542 is connected to one of sides of the base portion 541 which has a generally rectangular shape in the plan view, and the extension portion 543 is connected to another side of the base portion 541 opposite to the extension portion 542. The main terminal 91 is connected to the extension portion 542, and a support frame 98 (described later) is connected to the extension portion 543. The lead frame elements may be connected only to the extension portions 542 and 543 or may be connected across the base portion 541 and the extension portions 542 and 543. The extension portions 542 and 543 may be eliminated, and the lead frame elements may be connected to the base portion 541.

The relay wiring 55 is connected to the drain electrode 40D of the semiconductor element 40L, the substrate connection portion 80, and the main terminal 93. The relay wiring 55 electrically connects the substrate connection portion 80 and the drain electrode 40D of the semiconductor element 40L. The relay wiring 55 electrically connects the source electrode 40S of the semiconductor element 40H and the drain electrode 40D of the semiconductor element 40L to the main terminal 93. As an example, the relay wiring 55 has a base portion 551 and extension portions 552, 553, and 554. The base portion 551 encloses the semiconductor element 40L in a plan view. The base portion 551 has a generally rectangular shape in the plan view with the Y direction as the longitudinal direction.

The extension portions 552 and 553 extend from the base portion 551 in the Y direction. The length in the X direction of each of the extension portions 552 and 553, that is, the width, is narrower than the width of the base portion 551. The extension portions 552 and 553 each provide at least a portion of the area to which the lead frame elements including the external connection terminals 90 are connected. The extension portion 552 is connected to one of sides of the base portion 551 which has a generally rectangular shape in a plan view, and the extension portion 553 is connected to another side of the base portion 551 opposite to the extension portion 552. The main terminal 93 is connected to the extension portion 552, and the support frame 98 is connected to the extension portion 553. The lead frame elements may be connected only to the extension portions 552 and 553 or may be connected across the base portion 551 and the extension portions 552 and 553. The extension portions 552 and 553 may be eliminated, and the lead frame elements may be connected to the base portion 551.

The extension portion 554 encloses the substrate connection portion 80 in a plan view. The extension portion 554 is connected to one of the sides of the base portion 551 which has a generally rectangular shape in the plan view. The extension portion 554 extends from the side of the base portion 551 facing the P wiring 54 toward the base portion 541 in the X direction. In the Y direction, the length of the extension portion 554 is shorter than the length of the base portion 551. The relay wiring 55 has a generally L-shape in the plan view.

The N wiring 56 is connected to the substrate connection portion 81 and the main terminal 92. The N wiring 56 electrically connects the substrate connection portion 81 and the main terminal 92. The N wiring 56 encloses the substrate connection portion 81 in a plan view. As an example, the N wiring 56 has a generally rectangular shape in the plan view with the Y direction as the longitudinal direction.

In the front surface metal body 52, the P wiring 54 and the relay wiring 55 are arranged side by side in the X direction. The N wiring 56 is disposed between the base portion 541 and the base portion 551 in the X direction. The N wiring 56 is aligned with the extension portion 554 in the Y direction.

The front surface metal body 62 has an N wiring 64 and a relay wiring 65. The N wiring 64 and the relay wiring 65 are electrically separated from each other by a predetermined interval (gap). The gap is filled with the sealing body 30.

The N wiring 64 is connected to the source electrode 40S of the semiconductor element 40L and the substrate connection portion 81. The N wiring 64 electrically connects the source electrode 40S of the semiconductor element 40L and the substrate connection portion 81. The N wiring 64, together with the N wiring 56 of the substrate 50 and the substrate connection portion 81, electrically connects the source electrode 40S of the semiconductor element 40L to the main terminal 92.

The N wiring 64 has a base portion 641 and an extension portion 642. The N wiring 64 has a substantially L-shape in a plan view. The base portion 641 has a generally rectangular shape in a plan view with the Y direction as the longitudinal direction. The base portion 641 encloses the semiconductor element 40L in the plan view. The extension portion 642 is connected to one of sides of the base portion 641 which has a generally rectangular shape in the plan view. The extension portion 642 extends from the side of the base portion 641 facing the relay wiring 65 toward the base portion 651 in the X direction. At least a portion of the extension portion 642 overlaps with the N wiring 56 in the plan view.

The relay wiring 65 is connected to the source electrode 40S of the semiconductor element 40H and the substrate connection portion 80. The relay wiring 55 electrically connects the source electrode 40S of the semiconductor element 40H and the substrate connection portion 80. The relay wiring 65 includes a base portion 651 and an extension portion 652. The relay wiring 65 has a substantially L-shape in a plan view. The base portion 651 has a substantially rectangular shape in a plan view. The base portion 651 encloses the semiconductor element 40H in the plan view. The extension portion 652 is connected to one of sides of the base portion 651 which has a generally rectangular shape in the plan view. The extension portion 652 extends from the side of the base portion 651 facing the N wiring 64 toward the base portion 641 in the Y direction. At least a portion of the extension portion 652 overlaps with the extension portion 554 of the relay wiring 55 in the plan view.

The N wiring 64 and the relay wiring 65 are arranged side by side in the X direction. The base portion 641 and the base portion 651 are arranged side by side in the X direction. The source electrode 40S of the semiconductor element 40L is electrically connected to the base portion 641. The source electrode 40S of the semiconductor element 40H is electrically connected to the base portion 651. The extension portions 642 and 652 are aligned in the Y direction.

The back surface metal bodies 53 and 63 are electrically separated from the circuit including the semiconductor element 40 and the front surface metal bodies 52 and 62 by the insulating base members 51 and 61. The back surface metal bodies 53 and 63 may be referred to as metal base substrates. Heat generated from the semiconductor element 40 is transferred to the back surface metal bodies 53 and 63 via the front surface metal bodies 52 and 62 and the insulating base members 51 and 61. The back surface metal bodies 53 and 63 provide a heat dissipation function.

As an example, the back surface metal bodies 53 and 63 each have a substantially rectangular shape in the plan view. The back surface metal bodies 53 and 63 are so-called solid conductors disposed on substantially the entire region of the back surfaces of the insulating base members 51 and 61. Alternatively, the back surface metal bodies 53 and 63 may be patterned so as to substantially coincide with the front surface metal bodies 52 and 62 in the plan view.

In order to further enhance the heat dissipation effect, at least one of the back surface metal bodies 53 and 63 may be exposed from the sealing body 30. In the present embodiment, the back surface metal body 53 is exposed from the first surface 30a of the sealing body 30, and the back surface metal body 63 is exposed from the second surface 30b of the sealing body 30. The exposed surface of the back surface metal body 53 is substantially flush with the first surface 30a. The exposed surface of the back surface metal body 63 is substantially flush with the second surface 30b. The back surface metal bodies 53 and 63 form the back surfaces 50b and 60b of the substrates 50 and 60.

The conductive spacer 70 provides a spacer function of securing a predetermined interval between the semiconductor element 40 and the substrate 60. The conductive spacer 70 ensures the height of wires for electrically connecting the signal terminals 94 to the corresponding pads 40P of the semiconductor element 40. The conductive spacer 70 is located on an intermediate position of an electrical conduction path and a thermal conduction path between the source electrode 40S of the semiconductor element 40 and the substrate 60, and provides a wiring function and a heat dissipation function. The conductive spacer 70 contains a metal material, such as Cu, that has favorable electrical and thermal conductivity.

The conductive spacer 70 may be referred to as a terminal, a terminal block, a metal block, or the like. The semiconductor device 20 includes the conductive spacers 70 whose number is identical to the number of the semiconductor elements 40. Specifically, the semiconductor device 20 includes two conductive spacers 70. The conductive spacers 70 are individually connected to the semiconductor elements 40. The conductive spacer 70 is a columnar body having a size substantially the same as or slightly smaller than that of the source electrode 40S in a plan view. One of the conductive spacers 70 electrically connects the source electrode 40S of the semiconductor element 40H and the relay wiring 65. The other conductive spacer 70 electrically connects the source electrode 40S of the semiconductor element 40L and the N wiring 64.

The substrate connection portions 80 and 81 electrically connect the front surface metal body 52 of the substrate 50 and the front surface metal body 62 of the substrate 60. That is, the substrate connection portions 80 and 81 connect the substrates to each other. The substrate connection portion 80 electrically connects the relay wirings 55 and 65. The substrate connection portion 80 is disposed between the semiconductor element 40H and the semiconductor element 40L in the X direction. The substrate connection portion 80 is disposed in an overlapping region between the extension portion 554 of the relay wiring 55 and the extension portion 652 of the relay wiring 65 in the plan view. The substrate connection portion 81 is also disposed between the semiconductor element 40H and the semiconductor element 40L in the X direction. The substrate connection portion 81 is disposed in an overlapping region between the N wiring 56 and the extension portion 642 of the N wiring 64 in the plan view.

As an example, each of the substrate connection portions 80 and 81 is a metal columnar body. In the Z direction, a bonding material 103 is interposed between one of the ends of the substrate connection portion 80 and the relay wiring 55. The bonding material 103 is also interposed between the other end of the substrate connection portion 80 and the relay wiring 65. In the Z direction, the bonding material 103 is interposed between one of the ends of the substrate connection portion 81 and the N wiring 56, and the bonding material 103 is also interposed between the other end of the substrate connection portion 81 and the N wiring 64.

Alternatively, the substrate connection portions 80 and 81 may be continuously connected to at least one of the front surface metal bodies 52 and 62. In other words, the substrate connection portions 80 and 81 may be provided integrally with the front surface metal bodies 52 and 62 as part of the substrates 50 and 60. The substrate connection portions 80 and 81 may be configured to include only the bonding material 103.

The external connection terminal 90 is a terminal for electrically connecting the semiconductor device 20 to an external device. The external connection terminal 90 is formed using a metal material having favorable conductivity such as copper. The external connection terminal 90 is, for example, a plate member. The external connection terminal 90 may be referred to as a “lead”. The external connection terminal 90 include main terminals 91, 92, and 93 and a signal terminal 94. The main terminals 91, 92, and 93 are external connection terminals 90 that are electrically connected to the main electrodes of the semiconductor elements 40. The signal terminal 94 include a signal terminal 94H on the upper arm 9H side and a signal terminal 94L on the lower arm 9L side.

The main terminals 91 and 92 are external connection terminals 90 that are electrically connected to the power supply lines 7 and 8 described above. The main terminal 91 is electrically connected to the positive terminal of the smoothing capacitor 5. The main terminal 91 may be referred to as a positive terminal, a high potential power supply terminal, a P terminal, or the like. The main terminal 91 is connected to the P wiring 54 of the front surface metal body 52. In other words, the main terminal 91 is electrically connected to the drain electrode 40D of the semiconductor element 40H that constitutes the upper arm 9H. The main terminal 91 is connected to the P wiring 54 near one end in the Y direction. The main terminal 91 extends in the Y direction and projects from the side surface 30c to the outside of the sealing body 30.

The main terminal 92 is electrically connected to the negative terminal of the smoothing capacitor 5. The main terminal 92 may be referred to as a negative terminal, a low potential power supply terminal, an N terminal, or the like. The main terminal 92 is connected to the N wiring 56 of the front surface metal body 52. In other words, the main terminal 92 is electrically connected to the source electrode 40S of the semiconductor element 40L that constitutes the lower arm 9L. The main terminal 92 is connected to the N wiring 56 near one end in the Y direction. The main terminal 92 extends in the Y direction and projects from the side surface 30c to the outside of the sealing body 30.

The main terminal 93 is electrically connected to the winding 3a (stator coil) of the corresponding phase of the motor generator 3. The main terminal 93 may be referred to as an O terminal, an AC terminal, or the like. The main terminal 93 is connected to the relay wiring 55 of the front surface metal body 52. In other words, the main terminal 93 is electrically connected to the connection point between the upper arm 9H and the lower arm 9L. The main terminal 93 is connected to the relay wiring 55 near one end in the Y direction. The main terminal 93 extends in the Y direction and projects from the side surface 30c to the outside of the sealing body 30.

The three main terminals 91, 92, and 93 are arranged side by side in the X direction. The main terminals 91, 92, and 93 are arranged in the following order in the X direction: the main terminal 91, the main terminal 92, and the main terminal 93. Adjacent main terminals have side surfaces facing each other over most of their entire length. For example, a side surface of main terminal 91 and a side surface of main terminal 92 face each other.

The signal terminal 94 is electrically connected to the pad 40P of the corresponding semiconductor element 40 via connection member such as a bonding wire 110. The signal terminal 94H is connected via the bonding wire 110 to the pad 40P of the semiconductor element 40H. The signal terminal 94L is connected via the bonding wire 110 to the pad 40P of the semiconductor element 40L. The signal terminal 94 extends in the Y direction and projects outside the sealing body 30 from the side surface 30d. The signal terminal 94 extends in the Y direction opposite to the main terminals 91, 92, and 93. As an example, the signal terminal 94 include three signal terminals 94H and three signal terminals 94L.

The external connection terminals 90 are configured as part of a lead frame 95 as shown in FIG. 8. The lead frame 95 includes the external connection terminals 90, an outer peripheral frame 96, tie bars 97, and support frames 98. Each of the external connection terminals 90 is fixed in series to the outer peripheral frame 96 and/or indirectly fixed via the tie bar 97. The outer peripheral frame 96 and the tie bars 97 are removed as unnecessary parts during the manufacturing process of the semiconductor device 20.

The support frame 98 is connected to the front surface metal body 52 together with the main terminals 91, 92, and 93. The support frames 98 supports the substrate 50 together with the main terminals 91, 92, and 93. In order to stably support the substrate 50, the support frames 98 are connected to the substrate 50 on the opposite side in the Y direction to the main terminals 91, 92, and 93. The support frames 98 are separated from the outer peripheral frame 96 and the tie bars 97 when the unnecessary parts are removed. The semiconductor device 20 includes two support frames 98. One of the support frames 98 is connected to a portion of the P wiring 54 including the extension portion 543, and the other is connected to a portion of the relay wiring 55 including the extension portion 553. The support frames 98 extend in the Y direction and project outside the sealing body 30 from the side surface 30d.

The number of signal terminals 94 included in the lead frame 95 is not particularly limited. For example, the number of signal terminals 94 may be the same as the total number of pads 40P of the semiconductor element 40 arranged on the substrate 50. In multiple semiconductor elements 40, the same type of pads 40P may be connected to a common signal terminal 94 so that the number of signal terminals 94 may be less than the total number of pads 40P of the semiconductor elements 40.

As an example, the lead frame 95 has five signal terminals 94H and five signal terminals 94L. Then, depending on the number of pads 40P of the semiconductor element 40 mounted on the substrate 50, unnecessary signal terminals 94 are cut off after the sealing body 30 is formed. In the present embodiment, since the number of pads 40P of the semiconductor element 40H is three, three of the signal terminals 94H are provided for connection with the pads 40P, and the remaining two are cut off. Similarly, of the signal terminals 94L, three are provided for connection to the pads 40P, and the remaining two are cut off. Therefore, the semiconductor device 20 has a terminal remainder 99 which is the remaining portion after the part is cut off. The semiconductor device 20 has four terminal remainders 99.

The signal terminals 94H and 94L are arranged such that the distances between their respective tip positions and the centers of the corresponding pads 40P of the semiconductor element 40 are substantially equal to each other. The center is the central position of the pads 40P in the arrangement direction (X direction) of the pads 40P. Each of the signal terminals 94H and 94L has a straight portion 941 and an extension portion 942. The straight portion 941 is a portion that extends in the Y direction, and at least a portion of the straight portion 941 is disposed outside the sealing body 30. The extension portion 942 is a portion that continuously connects to one of the ends of the straight portion 941 and extends toward the corresponding pad 40P. At least a part of the extension portion 942 is covered by the sealing body 30. The multiple extension portions 942 extend radially from the center of the pads 40P of the corresponding semiconductor element 40, and are arranged in a generally fan-shaped configuration as a whole. This allows the bonding wires 110 to have approximately equal lengths.

As described above, in the semiconductor device 20 according to the present embodiment, the multiple semiconductor elements 40 constituting the upper-lower arm circuit 9 for one phase is sealed by the sealing body 30. The sealing body 30 integrally seals the multiple semiconductor elements 40, a portion of the substrate 50, a portion of the substrate 60, the multiple conductive spacers 70, the substrate connection portions 80 and 81, and a portion of each of the external connection terminals 90. The sealing body 30 seals the insulating base member 51 and 61 and the front surface metal bodies 52 and 62 of the substrates 50 and 60.

The semiconductor element 40 is disposed between the substrates 50 and 60 in the Z direction. The semiconductor element 40 is interposed between the substrates 50 and 60 disposed to face each other. Thereby, the heat of the semiconductor element 40 can be dissipated on both sides in the Z-direction. The semiconductor device 20 has a double-sided heat dissipation structure. The back surface 50b of the substrate 50 is substantially flush with the first surface 30a of the sealing body 30. The back surface 60b of the substrate 60 is substantially flush with the second surface 30b of the sealing body 30. Since the back surfaces 50b and 60b are exposed surfaces, it is possible to enhance the heat dissipation.

### Manufacturing Method

Next, an example of a method for manufacturing the semiconductor device 20 will be described.

First, the semiconductor element 40, the substrates 50 and 60, the conductive spacer 70, the substrate connecting portions 80 and 81, and the lead frame 95 are prepared. As illustrated in FIG. 8, the lead frame 95 includes the external connection terminals 90. The lead frame 95 is formed by performing processing, such as pressing, on a metal plate. The external connection terminals 90 are supported by the outer peripheral frame 96 directly and/or via tie bars 97.

Next, the substrate 50 and the lead frame 95 are bonded together. First, the substrate 50 and the lead frame 95 are positioned relative to each other so that bonding portions between the lead frame 95 and the front surface metal body 52 overlap each other. In this positioned state, the front surface metal body 52 and the lead frame 95 are bonded together by a solid-state bonding. Specifically, the main terminals 91, 92, 93 and the support frame 98 are bonded to the front surface metal body 52. FIG. 8 illustrates the bonded state.

Examples of the solid-state bonding include an ultrasonic bonding, a room temperature bonding, a friction stir bonding, a diffusion bonding, and a friction welding. In the present embodiment, as an example, an ultrasonic bonding is adopted. In the solid-state bonding, particularly, in the ultrasonic bonding, the bonding is easier when no plating film is formed on the surfaces of metals of the front surface metal body 52 and the lead frame 95. Therefore, the substrate 50 and the lead frame 95 are bonded together before a plating process.

Next, the plating process is performed. A plating film is formed on the surfaces of the front surface metal body 52 and the lead frame 95 so as to cover the bonded portion (solid-state bonded portion) between the front surface metal body 52 and the lead frame 95. The plating film includes, for example, a film containing nickel as a main component. In the present embodiment, as an example, a base film is formed by electroless Ni plating containing P (phosphorus), and then a top film is formed by Au plating.

Next, the semiconductor element 40 and the substrate connection portions 80 and 81 are bonded to the substrate 50. Also, the conductive spacer 70 is bonded to the semiconductor element 40. That is, the connection objects to be connected using the bonding materials 100, 101, and 103 are bonded to the substrate 50. Specifically, the drain electrode 40D of the semiconductor element 40 and the front surface metal body 52 are bonded to each other by the bonding material 100. The source electrode 40S and the conductive spacer 70 are bonded to each other by the bonding material 101. The substrate connection portions 80 and 81 and the front surface metal body 52 are bonded to each other by the bonding material 103. In the present embodiment, as an example, solder is used as the bonding materials 100, 101, and 103, so that bonding can be performed all at once by reflowing.

Next, wire bonding is performed. Specifically, the pads 40P of the semiconductor element 40H and the signal terminals 94H are electrically connected by bonding wires 110. Similarly, the pads 40P of the semiconductor element 40L and the signal terminals 94L are electrically connected by bonding wires 110.

Next, the substrate 60 is bonded. The conductive spacer 70 and the front surface metal body 62 are bonded to each other by the bonding material 102. The substrate connection portions 80 and 81 are bonded to the front surface metal body 62 by the bonding material 103. For example, in the case of solder, the bonding can be collectively performed all at one by reflowing.

Next, the sealing body 30 is formed. In the present embodiment, the sealing body 30 is formed by a transfer molding method. For example, the sealing body 30 is molded so as to completely cover the substrates 50 and 60, and then cut after the molding. The sealing body 30 is cut together with part of the back surface metal bodies 53 and 63 of the substrates 50 and 60. As a result, the back surfaces 50b and 60b are exposed. The back surface 50b is substantially flush with the first surface 30a of the sealing body 30, and the back surface 60b is substantially flush with the second surface 30b of the sealing body 30. Alternatively, the sealing body 30 may be molded in a state where at least one of the back surfaces 50b and 60b is pressed against and in close contact with a cavity wall surface of a molding die. In this case, at least one of the back surfaces 50b and 60b is exposed from the sealing body 30 when the sealing body 30 is molded.

Next, unnecessary portions of the lead frame 95, such as the outer peripheral frame 96, the tie bars 97, and the unused signal terminals 94, are removed. In this way, the semiconductor device 20 can be obtained.

### Bonded Portion and Peripheral Structure

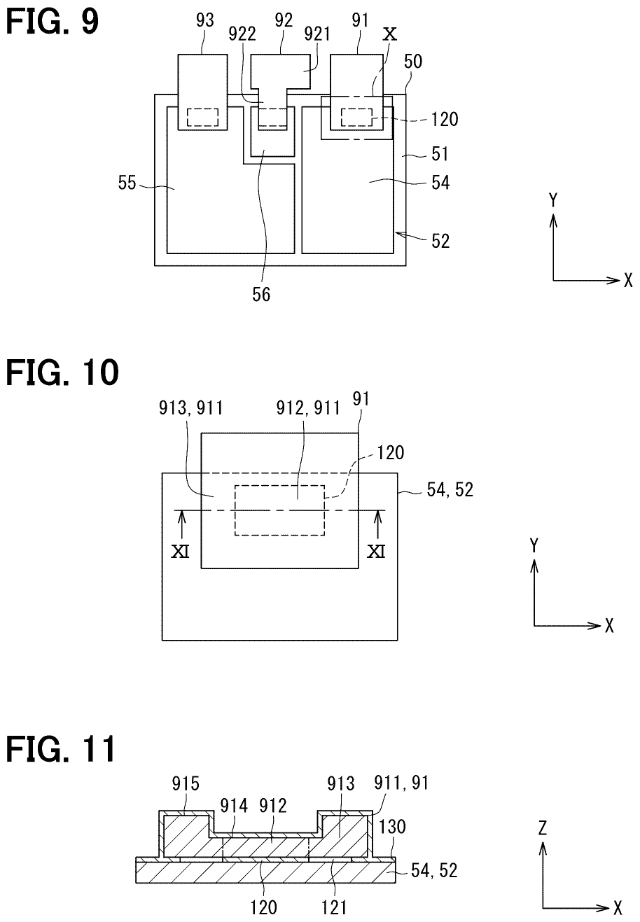

FIG. 9 is a plan view illustrating a connection structure between the front surface metal body 52 of the substrate 50 and the main terminals 91, 92, and 93. In FIG. 9, the front surface metal body 52 and the main terminals 91, 92, and 93 are illustrated in a simplified manner. FIG. 10 is an enlarged view of the region X indicated by the dashed line in FIG. 9. FIG. 11 is a cross-sectional view taken along a line XI-XI in FIG. 10.

As shown in FIG. 9, the main terminal 91 has a substantially constant length in a direction (X direction) perpendicular to the extending direction (Y direction), that is, has a substantially constant width. Similarly to the main terminal 91, the main terminal 93 also has a substantially constant width. The width of each of the main terminals 91 and 93 is greater than the width of the bonded portion 120 formed between the main terminals 91 and 93 and the front surface metal body 52. On the other hand, the main terminal 92 has a widened portion 921 and a narrowed portion 922 that is narrower than the widened portion 921. The narrowed portion 922 continuously connects to the widened portion 921 and forms the tip portion of the main terminal 92. In the main terminal 92, the width of the narrowed portion 922 is approximately the same as the width of the bonded portion 120. The width of the widened portion 921 is greater than the width of the bonded portion 120. Of the main terminals 91, 92, and 93, the main terminals 91 and 93 correspond to wide terminals. The bonded portion 120 corresponds to the solid-state bonded portion. The widened portion 921 may correspond to a first portion of the main terminal 92 and the narrowed portion 922 may correspond to a second portion of the main terminal 92.

As shown in FIGS. 10 and 11, the main terminal 91 as the wide terminal has an overlapping region 911 overlapping with the front surface metal body 52 in the plan view, and the overlapping region 911 includes a bonded region 912 and a non-bonded region 913. The bonded region 912 is a region that overlaps with the bonded portion 120 in the plan view. The bonded region 912 is the region providing the bonded portion 120. The bonded portion 120 and the bonded region 912 have, for example, rectangular shapes in the plan view. The non-bonded region 913 is a part of the overlapping region 911 excluding the bonded region 912. In FIG. 10, a part inside a broken line indicating the bonded portion 120 corresponds to the bonded region 912, and a part outside the broken line indicating the bonded portion 120 corresponds to the non-bonded region 913.

The non-bonded region 913 is disposed adjacent to the bonded region 912 at least in the width direction. In the present embodiment, as an example, the non-bonded region 913 surrounds the bonded region 912, as shown in FIG. 10. The non-bonded region 913 surrounds the entire perimeter of the bonded region 912. The bonded region 912 is located at the center of the overlapping region 911 and the non-bonded region 913 is disposed on the periphery of the bonded region 912. The non-bonded region 913 is located at both ends of the overlapping region 911 in the width direction, and at both ends of the overlapping region 911 in the extending direction. The non-bonded region 913 is adjacent to each of four sides of the bonded region 912 having the rectangular shape in the plan view.

As shown in FIG. 11, the bonded region 912 forms the bonded portion 120 with the P wiring 54 that is the front surface metal body 52. The bonded portion 120 of the present embodiment is an ultrasonic bond. The non-bonded region 913 does not form the bonded portion 120, so a gap 121 is provided between the non-bonded region 913 and the P wiring 54. The gap 121 is very small, and about several tens of μm. The gap 121 formed by ultrasonic bonding is 30 μm or less.

The semiconductor device 20 includes a plating film 130. The plating film 130 is provided on the lead frame 95 including the main terminal 91 and on the front surface metal body 52 so as to cover the bonded portion 120. The plating film 130 is formed by a plating process after the ultrasonic bonding. As described above, the plating film 130 contains nickel. The plating film 130 may be disposed in the gap 121. In other words, the plating film 130 may be disposed on facing surfaces of the non-bonded region 913 and the P wiring 54, which form the gap 121. The plating film 130 may be provided only in a portion of the gap 121, or may be provided up to an inner position of the gap 121 so as to contact the bonded portion 120. In the present embodiment, as an example, the plating film 130 is provided only in a partial range from the opening of the gap 121 between the facing surfaces of the non-bonded region 913 and the P wiring 54.

The thickness of the main terminal 91 may be substantially uniform over the entire area, or may vary partially. In the present embodiment, as an example, the overlapping region 911 has a thin portion 914 and a thick portion 915. The thin portion 914 includes at least the bonded region 912. The thin portion 914 is the portion that comes into contact with an ultrasonic tool during the ultrasonic bonding. The thin portion 914 is provided so as to enclose the bonded region 912, and therefore the bonded portion 120, in the plan view. The outer peripheral portion of the thin portion 914 forms the non-bonded region 913.

The thick portion 915 includes the bonded region 912. The thick portion 915 is disposed at both ends of the main terminal 91 in the width direction. In other words, the thin portion 914 is located between the thick portions 915. The thickness of the thick portion 915 is approximately equal to the thickness of the portion of the main terminal 91 other than the overlapping region 911. A main portion of the non-bonded region 913 is thicker than the bonded region 912. The region between the dashed dotted lines shown in FIG. 11 is the bonded region 912.

Of the wide terminals, the main terminal 91 has been described above, but the main terminal 93 has a similar structure.

### Summary of First Embodiment

It is conceivable that the main terminal bonded to the front surface metal body of the substrate may have a structure in which an inner end (first end) thereof providing the bonded portion has the same width as the bonded portion, and an outer end (second end) thereof is wider than the bonded portion. By reducing the width of the inner end of the main terminal, for example, it becomes easier to control the precision of the inclination of the bonding surface. By increasing the width of the outer end of the main terminal, for example, it becomes possible to allow a large current to flow. For example, the inductance can be reduced. However, the electric field will be concentrated at the corners of the boundary between the inner end and the outer end of the main terminal, resulting in reduction of the durable life.

In the present embodiment, the semiconductor device 20 includes the main terminal 91 as the wide terminal. The main terminal 91 has a non-bonded region 913. The non-bonded region 913 is adjacent to the bonded region 912 at least in the width direction (X direction). In other words, the width of the main terminal 91 (the width of the overlapping region 911) is wider than the width of the bonded portion 120. With this configuration, the main terminal 91 has less change in width. Therefore, the electric field concentration can be suppressed, and the durable life of the main terminal 91 can be improved. Further, the main terminal 91 can allow a large current to pass therethrough. Thus, the inductance can be reduced. Since the width of the bonded portion 120 (bonded region 912) is smaller than the width of the overlapping region 911, the precision of the inclination of the bonding surface can be easily controlled.

In a configuration in which a plating film is provided so as to cover the bonded portion, that is, in a configuration in which the plating film 130 is formed after the solid-state bonding, a plating solution residue may cause a problem. If the plating solution residue occurs, the residue may seep out during a subsequent process, such as a solder reflow process, and may cause, for example, a decrease in the adhesion of the front surface metal body to the sealing body and a decrease in the wettability of the solder (bonding material). If the main terminal has multiple bonded portions, the plating solution tends to remain between the bonded portions, resulting in generation of the plating solution residue.

In the present embodiment, the main terminal 91 has one bonded portion 120. The non-bonded region 913 is open laterally. Therefore, even if the plating solution comes into between the non-bonded region 913 and the front surface metal body 52, the plating solution can be easily discharged. The plating solution is less likely to remain in the gap 121 between the non-bonded region 913 and the front surface metal body 52. This makes it possible to suppress the plating solution from remaining in the gap 121, that is, to suppress the occurrence of plating solution residue.

According to the semiconductor device 20 of the present embodiment, as described above, it is possible to improve the durable life of the main terminal 91 while suppressing a problem caused by the plating solution residue. The semiconductor element 40 is connected to the front surface metal body 52 via the bonding material 100. By suppressing the plating solution residue, it is possible to suppress a decrease in the reliability of the connection between the semiconductor element 40 and the front surface metal body 52. The same applies to the main terminal 93, which is the wide terminal.

The positional relationship between the main terminals 91 and 93, which are wide terminals, and the semiconductor element 40 is not particularly limited. In the present embodiment, the main terminals 91 and 93 and the corresponding semiconductor elements 40H and 40L are aligned in the extension direction (Y direction) of the main terminals 91 and 93. In such a configuration, if the plating solution residue occurs, the wettability of the solder, which is the bonding material 100, may decrease, and the reliability of the connection between the semiconductor element 40 and the front surface metal body 52 may decrease. However, the configuration described above can suppress the occurrence of the plating solution residue. Therefore, the deterioration of the connection reliability between the semiconductor element 40 and the front surface metal body 52 can be suppressed.

The semiconductor device 20 of the present embodiment includes the sealing body 30. The configuration described above suppresses the seepage of the plating solution residue onto the surface of the front surface metal body 52. Therefore, the decrease in the adhesion of the sealing body 30 to the front surface metal body 52 can be suppressed.

The non-bonded region 913 of the present embodiment surrounds the bonded region 912. Specifically, the non-bonded region 913 entirely surrounds the bonded region 912. The bonded region 912 is located inside the non-bonded region 913. The gap 121 formed between the non-bonded region 913 and the front surface metal body 52 is open to the outside around its entire periphery. Therefore, the plating solution can be effectively restricted from remaining in the gap 121. With this configuration, even if misalignment occurs in any direction, the bonding area can be ensured.

The bonded portion 120 of the present embodiment is the ultrasonic bond. In the case of the ultrasonic bonding, friction is not possible on or after the second point in a multi-point bonding, so the bonding strength decreases. As described above, each of the main terminals 91 and 93 has the single bonded portion 120. That is, the number of bonded portion(s) 120 in each of the main terminals 91 and 93 is one. Each of the man terminals 91 and 93 is bonded to the front surface metal body 52 at one point. Therefore, the bonding strength can be ensured while employing the ultrasonic bonding. In other words, durability can be improved.

In the present embodiment, the non-bonded region 913 has a portion that is thicker than the bonded region 912. As such, the bonded region 912 is thin. Therefore, the bonded portion 120 can be formed with a small load. In other words, the load during the ultrasonic bonding can be reduced, and damage to the substrate 50 can be reduced. Since the non-bonded region 913 has the portion that is thicker than the bonded region 912, the rigidity of the overlapping region 911, and therefore the main terminal 91, can be ensured.

In the present embodiment, the gap 121 between the non-bonded region 913 and the front surface metal body 52 is 30 um or less. By narrowing the gap 121 in this manner, the plating solution is less likely to enter the gap 121. Therefore, it is possible to suppress the occurrence of plating solution residue. In a configuration that employs the sealing body 30 made of a resin mixed with filler, the filler is less likely to enter gap 121. This makes it possible to suppress a decrease in durability caused by localized increase in stress due to the filler being bitten into the material.

### Modifications

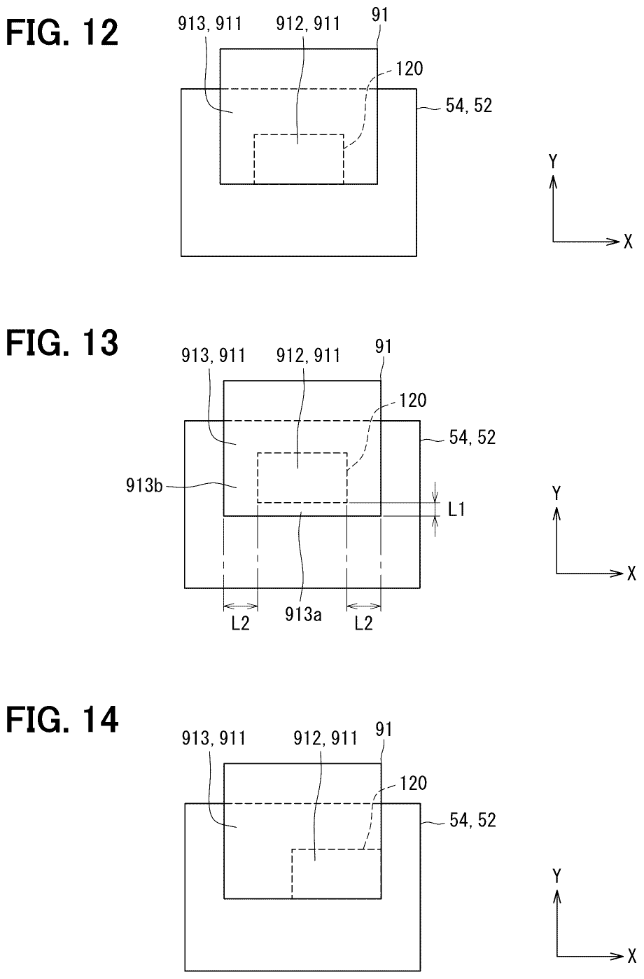

The configuration in which the non-bonded region 913 surrounds the bonded region 912 is not limited to the example shown in FIG. 10 in which the non-bonded region 913 entirely surrounds the bonded region 912. For example, as shown in FIG. 12, the non-bonded region 913 may be provided adjacent to three sides of the bonded region 912. In FIG. 12, the bonded region 912 is provided over a predetermined range from the tip of the main terminal 91. The non-bonded region 913 is adjacent to three of the four sides of the bonded region 912, excluding the side forming the tip of the main terminal 91.

In the configuration in which the non-bonded region 913 entirely surrounds the bonded region 912, for example, the bonded region 912 may be offset toward the tip of the main terminal 91 from the center position of the overlapping region 911, as shown in FIG. 13. The non-bonded region 913 has a tip portion 913a located on the tip side of the main terminal 91 in the extension direction, and lateral portions 913b adjacent to the bonded region 912 in the width direction. The length L1 of the tip portion 913a in the extension direction (Y direction) is shorter than the length L2 of the lateral portion 913b in the width direction (X direction). That is, the non-bonded region 913 is smaller on the semiconductor element 40 side in the extension direction (Y direction) than in the width direction (X direction). As a result, since the gap 121 on the semiconductor element 40 side is small, it is possible to effectively suppress the plating solution from seeping out to the semiconductor element 40 side. Therefore, the deterioration of the connection reliability between the semiconductor element 40 and the front surface metal body 52 can be effectively suppressed.

Note that the configuration shown in FIG. 12 does not have the tip portion 913a. As a result, the non-bonded region 913 is smaller on the semiconductor element 40 side in the extension direction (Y direction) than in the width direction (X direction). Therefore, the deterioration of the connection reliability between the semiconductor element 40 and the front surface metal body 52 can be effectively suppressed.

In the overlapping region 911, the positions of the bonded region 912 and the non-bonded region 913 are not particularly limited. The non-bonded region 913 may be provided adjacent to the single bonded region 912 of the overlapping region 911 at least in the width direction. For example, as shown in FIG. 14, the non-bonded region 913 may be provided adjacent to two sides of the bonded region 912. The bonded region 912 is provided over a predetermined range from the tip of the main terminal 91 in the Y direction. The bonded region 912 is provided over a predetermined range from one end of the main terminal 91 in the X direction. The non-bonded region 913 is adjacent to one side of the bonded region 912 in the X direction. The non-bonded region 913 is adjacent to one side of the bonded region 912 in the Y direction.

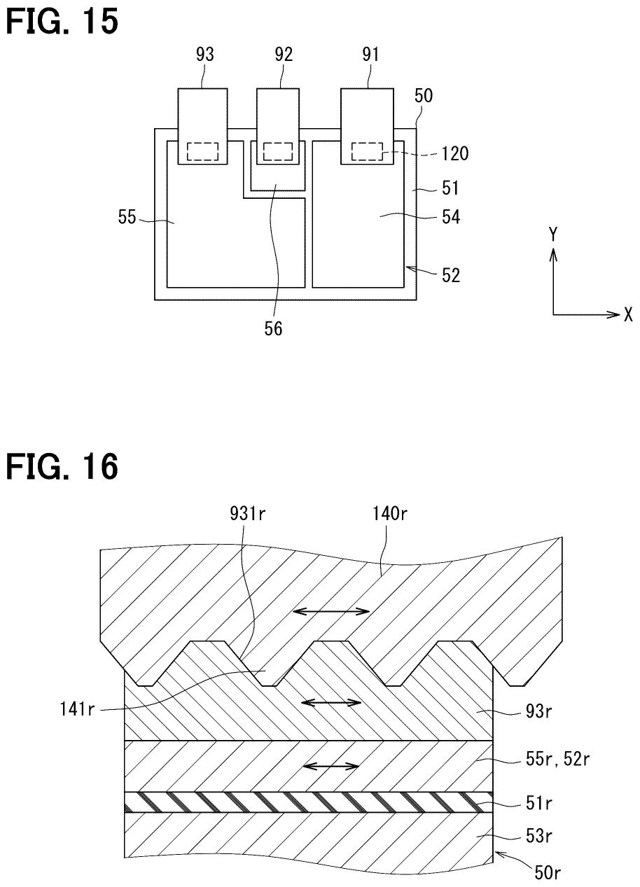

Although an example in which the main terminal 92 located in the middle among the main terminals 91, 92, and 93 is excluded from the wide terminals has been shown, the present disclosure is not limited to such an example. As shown in FIG. 15, the main terminal 92 may be a wide terminal similar to the main terminals 91 and 93.

### Second Embodiment

The second embodiment is a modification based on the preceding embodiment, and the description of the preceding embodiment can be incorporated. In order to eliminate problems associated with ultrasonic bonding, various improvements may be made to the main terminal and/or the substrate.

### Semiconductor Device

The basic configuration of the semiconductor device 20 according to the present embodiment is similar to the schematic configuration of the semiconductor device 20 shown in the preceding embodiment (see FIGS. 2 to 8).

Although not shown, the semiconductor device 20 includes a sealing body 30, a semiconductor element 40, substrates 50 and 60, a conductive spacer 70, substrate connection portions 80 and 81, and an external connection terminal 90. The semiconductor device 20 includes bonding materials 100 to 103 and a bonding wire 110.

The bonded portions 120 formed by a solid-state bonding are provided between the substrate 50 and the main terminals 91, 92, and 93. In the present embodiment, an ultrasonic bonding is used as the solid-state bonding. The bonded portion 120 is an ultrasonic bond. The rest of the configuration is similar to the schematic configuration of the semiconductor device 20 shown in the preceding embodiment.

### Damage to Substrate

FIG. 16 is a cross-sectional view illustrating a reference example. In the reference example, “r” is added to the end of the reference sign of a related component of the semiconductor device 20, and the sign thus obtained is used as the reference sign of each component. In FIG. 16, the energy applied by an ultrasonic tool and the energy transmitted to the object to be bonded are indicated by solid arrows. The size of the solid arrow indicates the magnitude of the energy. FIG. 16 shows an example of ultrasonic bonding between a main terminal 93r and a front surface metal body 52r (relay wiring 55r).

As shown in FIG. 16, an ultrasonic tool 140r has multiple protrusions 141r on its contact surface. The multiple protrusions 141r are provided at predetermined intervals. On the other hand, the main terminal 93r has multiple recesses 931r on an upper surface with which the ultrasonic tool 140r comes into contact. The multiple recesses 931r are provided at predetermined intervals. The protrusions 141r and the recesses 931r are provided so as to mesh with each other.

The ultrasonic tool 140r vibrates in a direction perpendicular to the Z direction in a state where the protrusions 141r and the recesses 931r are meshed with each other. The energy is transmitted from the ultrasonic tool 140r to the main terminal 93r, and further to the front surface metal body 52r located below the main terminal 93r. This vibration energy causes a relative displacement between the front surface metal body 52r and the back surface metal body 53r in a direction perpendicular to the Z direction. That is, stress is generated in the substrate 50r. Further, the ultrasonic vibration causes the substrate 50r to generate heat.

As a result, the substrate 50r, for example the insulating base member 51r, is damaged. If the insulating base member 51r is damaged, there is a fear that the insulation reliability will decrease. In particular, the damage to the substrate 50 is likely to be increased as the energy applied by the ultrasonic tool 140r is increased.

### Burrs

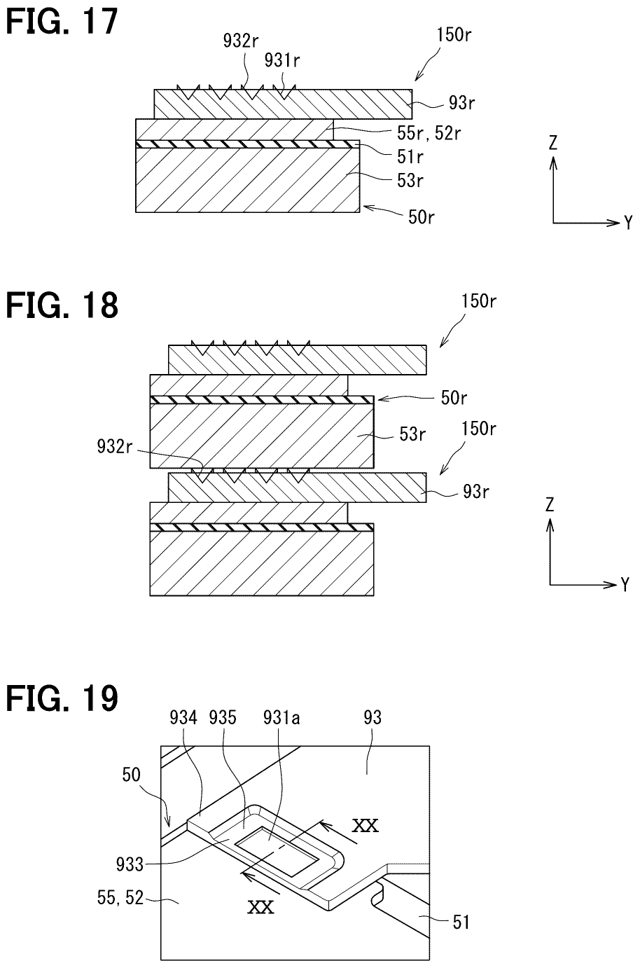

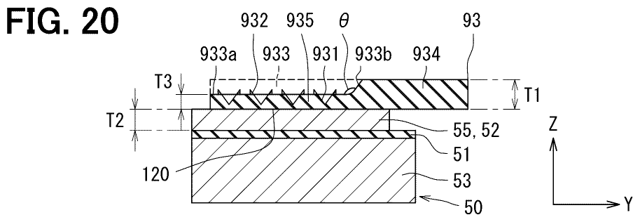

FIG. 17 is a cross-sectional view illustrating a reference example. FIG. 17 corresponds to FIG. 20, which will be described later. In the example shown in FIG. 17, a main terminal 93r is formed by pressing a metal plate material of a certain thickness, that is, a flat metal plate material.

The main terminal 93r has recesses 931r for ultrasonic bonding. The recesses 931r are formed by pressing. The main terminal 93 has burrs 932r formed due to the pressing near the open ends of the recesses 931r. A lead frame having such a main terminal 93r and the substrate 50r are bonded by the ultrasonic bonding to form a bonded body 150r of the lead frame and the substrate 50r.

FIG. 18 is a cross-sectional view illustrating a reference example. FIG. 18 shows the bonded body 150r in a packaged state. As shown in FIG. 18, multiple bonded bodies 150r are stacked in the Z direction and packaged. In FIG. 18, for simplicity, two bonded bodies 150r are shown.

In this packaged state, between two bonded bodies 150r adjacent to each other in the Z direction, the burrs 932r of the lower main terminals 93r come into contact with the back surface metal body 53 of the upper substrate 50r. This may cause scratches on the back surface metal body 53r or generate foreign matter.

### Structure around Bonded Portion

FIG. 19 is a perspective view illustrating the periphery of the bonded portion between the main terminal 93 and the relay wiring 55 of the front surface metal body 52 in the semiconductor device 20 of the present embodiment. FIG. 19 corresponds to a region XIX indicated by the dashed line in FIG. 8. FIG. 20 is a cross-sectional view taken along a line XX-XX in FIG. 19.

The main terminal 93 has a recessed portion 933 that is provided to include the bonded portion 120 in the plan view. The recessed portion 933 defines an opening on the upper surface of the main terminal 93 and has a predetermined depth in the Z direction. As a result, the thickness between a bottom surface 933a of the recessed portion 933 and the lower surface (bonded surface) of the main terminal 93, that is, the thickness of the portion where the recessed portion 933 is provided, is thinner than the other portions of the main terminal 93. The thickness T1 of a thick portion 934 of the main terminal 93 excluding the portion where the recessed portion 933 is provided is greater than the thickness T2 of the front surface metal body 52. On the other hand, the thickness T3 of a thin portion 935 in which the recessed portion 933 is provided is thinner than the thickness T2 of the front surface metal body 52. The thickness T3 of the thin portion 935 is the thickness of portions where the recesses 931 are not formed.

An ultrasonic tool comes into contact with the bottom surface 933a of the recessed portion 933. The recessed portion 933 provides an area over which the ultrasonic tool can ultrasonically vibrate. A portion of the ultrasonic tool is placed in the recessed portion 933. In the present embodiment, as an example, the recessed portion 933 is provided at the tip of the main terminal 93. The recessed portion 933 also defines the opening on the tip end surface of the main terminal 93.

In the X direction, which is the width direction, the main terminal 93 has thick portions 934 at both ends. The thin portion 935 has a generally rectangular shape in a plan view. The side surfaces 933b of the recessed portion 933 are provided on the three sides excluding the tip end side of the main terminal 93.

The multiple recesses 931 are formed on the bottom surface 933a of the recessed portion 933. The rectangular area indicated by the solid line in FIG. 19 indicates a formation area 931a of the recesses 931. The height of burrs 932 present near the open end of the recess 931 are smaller than the depth of the recessed portion 933. The burrs 932 are disposed entirely in the recessed portion 933.

### Summary of Second Embodiment

In the present embodiment, the thickness T3 of the thin portion 935 including the bonded portion 120 is smaller than the thickness T2 of the front surface metal body 52 (T3<T2). Therefore, it is possible to form the bonded portion 120 even if the energy applied by the ultrasonic tool is reduced. By reducing the energy, for example, the relative displacement between the front surface metal body 52 and the back surface metal body 53 can be suppressed. Therefore, damage to the substrate 50, for example, damage to the insulating base member 51, can be reduced.

In the present embodiment, the thickness T1 of the thick portion 934 is greater than the thickness T2 of the front surface metal body 52 (T1>T2). The thin portion 935 is provided locally. Therefore, it is possible to ensure the rigidity on the periphery of the bonded portion 120 in the main terminal 93. In particular, the thick portion 934 is located on both sides of the thin portion 935 in the width direction. Therefore, when the lead frame 95 is gripped and transported, the thick portion 934 on both the sides of the thin portion 935 functions as a beam, making it possible to suppress stress from concentrating on the bonded portion 120.

In the present embodiment, the height of the burrs 932 provided on the bottom surface 933a of the recessed portion 933 is smaller than the depth of the recessed portion 933. As a result, as in the reference example shown in FIG. 18, when the bonded bodies of the substrates 50 and lead frames 95, which are bonded by the ultrasonic bonding, are stacked and packed, the burrs 932 of the lower bonded body do not come into contact with the back surface metal body 53 of the upper bonded body. This can suppress the back surface metal body 53 from being scratched or foreign matter from being generated.

An angle θ between the bottom surface 933a and the side surface 933b of the recessed portion 933 is not particularly limited, but is preferably 45 degrees or more. It is also preferable that the corner between the bottom surface 933a and the side surface 933b be rounded. With this configuration, it possible to suppress stress concentration at the corner of the main terminal 93 having the thin portion 935. For example, it is possible to suppress cracks from occurring in the main terminal 93 due to stress concentration.

Although the main terminal 93 has been described above, the same applies to the other main terminals 91 and 92, which are bonded by the ultrasonic bonding.

The configuration described in the present embodiment can be combined with the configuration described in the preceding embodiment.

### Third Embodiment

The present embodiment is a modification based on the preceding embodiment, and the description of the preceding embodiment can be incorporated. In the present embodiment, another configuration that can suppress damage to the substrate due to the ultrasonic bonding is proposed.

### Ultrasonic Bonding Process

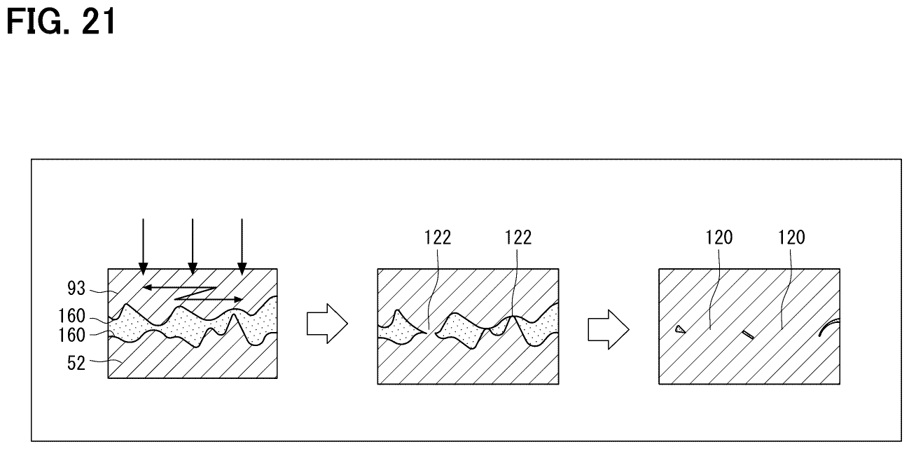

FIG. 21 is a cross-sectional view illustrating an ultrasonic bonding process. As an example, the objects to be bonded are the front surface metal body 52 and the main terminal 93.

Before the ultrasonic bonding, contamination 160 is present on the surfaces of the front surface metal body 52 and the main terminal 93 to be bonded. In the ultrasonic bonding, vibration energy is applied to the main terminal 93 while applying pressure thereto by an ultrasonic tool. As a result, contact points 122 of the front surface metal body 52 and the main terminal 93, which serve as a starting point of bonding, come into contact with each other at high speed, and a metallic bond is formed by friction and plastic flow. The metallic bond then spreads, forming the bonded portion 120.

### Manufacturing Method of Semiconductor Device

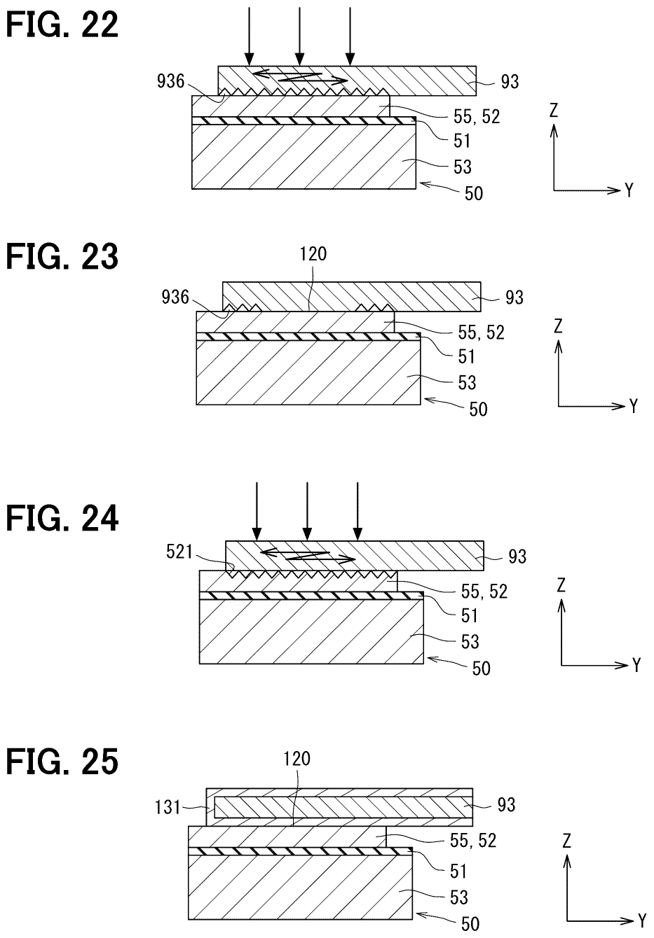

FIG. 22 is a cross-sectional view illustrating a method for manufacturing the semiconductor device 20 according to the present embodiment. FIG. 22 corresponds to FIG. 20. FIG. 22 shows ultrasonic bonding between the front surface metal body 52 (relay wiring 55) of the substrate 50 and the main terminal 93.

In the present embodiment, before the ultrasonic bonding, an uneven portion 936 is provided on the lower surface (bonding surface) of the main terminal 93. The uneven portion 936 is sometimes referred to as a roughened portion. Then, vibration energy is applied to the main terminal 93 having the uneven portion 936 while applying pressure thereto by an ultrasonic tool.

The uneven portion 936 is formed by, for example, a roughening treatment. Specifically, laser roughening, roughening plating, sandblasting, chemical treatment, and the like are possible. The uneven portion 936 having smaller pitch in projections and recesses is preferable. The pitch of projections and recesses of the uneven portion 936 is, for example, on the order of nanometer (nm) or micrometer (μm). The uneven portion 936 has extremely fine projections and recesses.

### Summary of Third Embodiment

In the present embodiment, the ultrasonic bonding is performed using the main terminal 93 having the uneven portion 936 on the bonding surface. With this configuration, it is possible to obtain sufficient bonding with smaller pressure and amplitude compared to the ultrasonic bonding between flat surfaces. In other words, the bonded portion 120 can be formed even if the energy applied by the ultrasonic tool is reduced. The reduction in energy reduces the stress generated in the substrate 50 and the heat generated from the substrate 50. Therefore, damage to the substrate 50, for example, damage to the insulating base member 51, can be reduced.

FIG. 23 shows an example of the semiconductor device 20 formed by the manufacturing method described above. FIG. 23 is an enlarged view of the periphery of the bonded portion 120 between the main terminal 93 and the substrate 50 in the semiconductor device 20. FIG. 23 corresponds to FIG. 20. The rest of the configuration is similar to the schematic configuration of the semiconductor device 20 described in the preceding embodiment.

The uneven portion 936 is provided so as to enclose the region where the bonded portion 120 is to be formed, prior to the ultrasonic bonding. The uneven portion 936 is provided taking into consideration misalignment. In the semiconductor device 20, the uneven portion 936 surrounds the bonded portion 120. The uneven portion 936 is adjacent to the bonded portion 120. The uneven portion 936 of the semiconductor device 20 is the portion that remains without being bonded by the ultrasonic bonding.

The number of sides on which the uneven portion 936 is adjacent to the bonded portion 120 is not particularly limited. The uneven portion 936 may be adjacent to only one side of the bonded portion 120, for example. The entire uneven portion 936 may contribute to the formation of the bonded portion 120, so that the semiconductor device 20 may have no uneven portion 936.

Although the main terminal 93 has been described above, the same applies to the other main terminals 91 and 92, which are bonded by the ultrasonic bonding.

### Modification

Although an example in which the energy during the ultrasonic bonding is reduced by providing the uneven portion 936 on the main terminal 93, the present disclosure is not limited to this example. As shown in FIG. 24, an uneven portion 521 may be provided on the upper surface (bonding surface) of the front surface metal body 52. FIG. 24 corresponds to FIG. 20.

The configuration described in the present embodiment can be combined with the configuration described in the preceding embodiment.

### Fourth Embodiment

The present embodiment is a modification based on the preceding embodiment, and the description of the preceding embodiment can be incorporated. In the present embodiment, another configuration that can suppress damage to the substrate due to the ultrasonic bonding is proposed.

FIG. 25 is an enlarged cross-sectional view of the periphery of the bonded portion 120 between the main terminal 93 and the substrate 50 in the semiconductor device 20 according to the present embodiment. FIG. 25 corresponds to FIG. 20.

As shown in FIG. 25, a plating film 131 is formed on the surface of the main terminal 93. A part of the plating film 131 forms the bonded portion 120. The bonded portion 120 contains the metal forming the plating film 131. In FIG. 25, the bonded portion 120 is illustrated in a simplified manner.

The plating film 131 is mainly made of a metal material different from the metal of the front surface metal body 52 and the metal of the main terminal 93. The metal as the main component of the plating film 131 is, for example, Pd or Au.

### Summary of Fourth Embodiment

According to the present embodiment, the bonding time can be reduced by diffusion of the different metals. Therefore, even if the energy applied by the ultrasonic tool is reduced, the bonded portion 120 can be formed. The reduction in energy can reduce damage to the substrate 50, for example, damage to the insulating base member 51.

Although the main terminal 93 has been described above, the same applies to the other main terminals 91 and 92, which are bonded by the ultrasonic bonding.

Although an example in which the plating film 131 is provided on the main terminal 93 has been described, the present disclosure is not limited to this example. A plating film mainly made of a metal material different from the metal of the front surface metal body 52 and the metal of the main terminal 93 may be provided on the surface of the front surface metal body 52.

The configuration of the present embodiment can be combined with the configurations described in the preceding embodiments, except for the configuration in which the plating film 130 is formed after the bonding and the configuration in which an uneven portion is provided on the bonding surface.

### Fifth Embodiment

Th present embodiment is a modification based on the preceding embodiment, and the description of the preceding embodiment can be incorporated. In the present embodiment, another configuration that can suppress damage to the substrate due to the ultrasonic bonding is proposed.

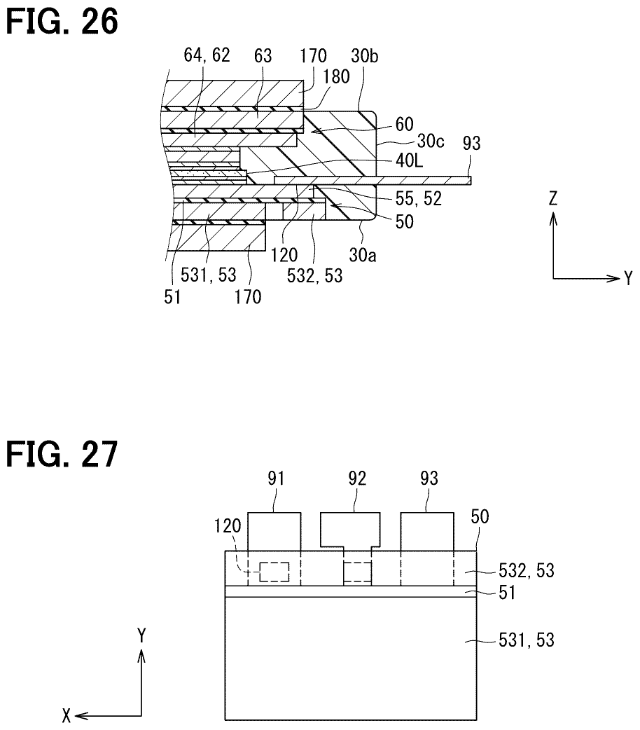

FIG. 26 is an enlarged cross-sectional view of the periphery of the bonded portion 120 between the main terminal 93 and the substrate 50 in the semiconductor device 20 according to the present embodiment.

The back surface metal body 53 of the substrate 50 is patterned. The back surface metal body 53 has a main portion 531 and a separation portion 532. The main portion 531 occupies most of the back surface metal body 53. The main portion 531 may be referred to as a main heat dissipation section. The main portion 531 encloses the semiconductor element 40 in a plan view.

The separation portion 532 is electrically separated from the main portion 531. Between the separation portion 532 and the main portion 531, there is a gap from which the metal body is removed. The separation portion 532 may be referred to as an island. The separation portion 532 is provided directly below the bonded portion 120. The separation portion 532 encloses the bonded portion 120 therein in a plan view. The rest of the configuration is similar to the schematic configurations of the semiconductor device 20 described in the preceding embodiments.

The semiconductor device 20 is cooled by a cooler 170. The cooler 170 cools the semiconductor device 20 by allowing a coolant to flow through a flow path provided therein. As the refrigerant flowing through the flow path, a phase-transition refrigerant such as water or ammonia, or a non-phase-transition refrigerant such as ethylene glycol-based refrigerant can be used. A heat conductive member 180 such as silicone gel is disposed between the cooler 170 and the semiconductor device 20. The heat conductive member 180 is sometimes referred to as a thermal interface material (TIM). The heat conductive member 180 follows the facing surfaces of the cooler 170 and the semiconductor device 20 and fills the gap between the facing surfaces.

As an example, the coolers 170 are disposed on both sides of the semiconductor device 20 in the Z direction. The coolers 170 are arranged in a layered manner on the semiconductor device 20. One of the coolers 170 is disposed so as to overlap the main portion 531 of the back surface metal body 53 in the plan view but not to overlap the separation portion 532. The cooler 170 is thermally connected to the main portion 531 of the back surface metal body 53. The cooler 170 cools the semiconductor device 20 via the main portion 531. The other cooler 170 is disposed so as to overlap the back surface metal body 63 in the plan view. The cooler 170 is thermally connected to the back surface metal body 63. The cooler 170 cools the semiconductor device 20 via the back surface metal body 63.

FIG. 27 shows an example of the pattern of the back surface metal body 53. The back surface metal body 53 has one main portion 531 and one separation portion 532. The separation portion 532 is provided so as to enclose the bonded portion 120 of each of the main terminals 91, 92, and 93 therein. The separation portion 532 is a common area for the main terminals 91, 92, and 93.

### Summary of Fifth Embodiment

According to the present embodiment, the separation portion 532 is provided immediately below the bonded portion 120. In other words, the separation portion 532 is provided immediately below the portion to which a load is applied during the ultrasonic bonding. The separation portion 532 is separated from the other portion of the back surface metal body 53 (that is, the main portion 531). Compared to an integral structure, the separation portion 532 is more easily deformed. Therefore, the separation portion 532 can suppress the occurrence of stress in the substrate 50 during the ultrasonic bonding. Therefore, damage to the substrate 50, for example, damage to the insulating base member 51, can be reduced.

Moreover, the separation portion 532 provided immediately below the bonded portion 120 is electrically separated from the main portion 531. Therefore, even if a crack occurs in the insulating base member 51 at the position overlapping with the separation portion 532 during the ultrasonic bonding, the insulation properties of the semiconductor device 20 can be ensured on the main portion 531 side.

The pattern of the back surface metal body 53 is not limited to the example shown in FIG. 27. For example, the separation portion 532 may be provided individually for each of the main terminals 91, 92, and 93. In other words, the back surface metal body 53 may have multiple separation portions 532.

The configuration of the present embodiment can be combined with the configuration described in the preceding embodiment.

### Other Embodiments

The disclosure in this description, drawings, and the like is not limited to the embodiments illustrated. The disclosure includes the illustrated embodiments and modifications by those skilled in the art based thereon. For example, the disclosure is not limited to the combinations of components and/or elements shown in the embodiments. The disclosure may be implemented in various combinations thereof. The disclosure may have additional parts that may be added to the embodiments. The disclosure includes modifications in which components and/or elements are omitted from the embodiments. The disclosure includes replacement or combination of components and/or elements between one embodiment and another embodiment, or combinations thereof. The technical scopes disclosed in the disclosure are not limited to the description of the embodiments. Some of the disclosed technical scopes are indicated by the description of the scope of claims and should be further understood to include meanings equivalent to the description of the scope of claims and all modifications within the scope.

The disclosure in the description, the drawings, and the like is not limited by the description of the scope of claims. The disclosure in the specification, the drawings, and the like includes the technical ideas described in the claims, and further extends to a wider variety of technical ideas than those in the claims. Thus, various technical ideas can be extracted from the disclosure of the description, the drawings, and the like without being restricted by the description of the scope of claims.

When an element or a layer is described as “disposed above”, “coupled to” “connected to” or “combined with”, the element or the layer may be directly disposed above, coupled to, connected to, or combined with another element or another layer, or an intervening element or an intervening layer may be present therebetween. In contrast, when an element is described as “directly disposed on,” “directly coupled to,” “directly connected to”, or “directly combined with” another element or another layer, there are no intervening elements or layers present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B.

Spatial relative terms “inside”, “outside”, “rear”, “bottom”, “low”, “top”, “high”, and the like are used herein to facilitate the description that describes relationships between one element or feature and another element or feature. Spatial relative terms can be intended to include different orientations of a device in use or operation, in addition to the orientations illustrated in the drawings. For example, when a device in a drawing is turned over, elements described as “below” or “directly below” other elements or features are oriented “above” the other elements or features. Therefore, the term “below” can include both above and below. The device may be oriented in another direction (rotated 90 degrees or in any other direction) and the spatially relative terms used herein are interpreted accordingly.

The configuration of the vehicle drive system 1 is not limited to the configuration described above. For example, an example in which the vehicle drive system 1 has one motor generator 3 has been described, but the vehicle drive system 1 is not limited thereto. The vehicle drive system 1 may have multiple motor generators. Although an example in which the power conversion device 4 includes the inverter 6 as the power conversion circuit has been described, the present disclosure is not limited thereto. For example, a configuration with multiple inverters may also be adopted. As another example, a configuration with at least one inverter and a converter may be adopted. Alternatively, a configuration with only one converter may be adopted.

Although an example in which the semiconductor element 40 has the MOSFET 11 as the switching element has been described, the present disclosure is not limited thereto. For example, an IGBT may be used as the switching element. IGBT is an abbreviation for Insulated Gate Bipolar Transistor.

The semiconductor device 20 may include multiple semiconductor elements 40 each constituting one arm. The semiconductor device 20 may include multiple semiconductor elements 40H each constituting the upper arm 9H, and multiple semiconductor elements 40L each constituting the lower arm 9L. The drain electrodes 40D of the multiple semiconductor elements 40H are connected to a common P wiring 54. The drain electrodes 40D of the multiple semiconductor elements 40L are connected to a common relay wiring 55.

Although an example in which the semiconductor device 20 constitutes the upper-lower arm circuit 9 for one phase has been described, the present disclosure is not limited thereto. The semiconductor device 20 may constitute only one arm. The semiconductor device 20 may constitute multiple upper-lower arm circuits 9 for multiple phases.

The number of main terminals bonded to the front surface metal body 52 of the substrate 50 is not particularly limited. The semiconductor device 20 may include at least one main terminal bonded to the front surface metal body 52.

The pattern of the front surface metal body 52 and the arrangement of the front surface metal body 52 and the main terminals 91, 92, and 93 are not limited to the examples described above.

Although an example in which the source electrode 40S is electrically connected to the front surface metal body 62 of the substrate 60 has been described, the present disclosure is not limited thereto. Instead of the substrate 60, a metal plate may be used. A configuration without the substrate 60, that is, a one-sided heat dissipation structure, may be adopted.

Although an example in which the semiconductor device 20 includes the conductive spacer 70, the present disclosure is not limited thereto. The semiconductor device 20 may not include the conductive spacer 70. For example, instead of the conductive spacer 70, the front surface metal body 62 of the substrate 60 may have a protrusion.

Although an example in which the semiconductor device 20 includes the sealing body 30 has been described, the present disclosure is not limited thereto. The semiconductor device 20 may not include the sealing body 30.

What is claimed is:

1. A semiconductor device comprising:
a semiconductor element having a first main electrode on a first surface and a second main electrode on a second surface opposite to the first surface in a thickness direction;
a substrate having an insulating base member, a front surface metal body disposed on a front surface of the insulating base member and electrically connected to the first main electrode, and a back surface metal body disposed on a back surface of the insulating base member opposite to the front surface of the insulating base member;
a bonding material interposed between the first main electrode and the front surface metal body and bonding the first main electrode and the front surface metal body;
a main terminal having a solid-state bonded portion bonded to the front surface metal body; and
a plating film disposed on the front surface metal body and the main terminal so as to cover the solid-state bonded portion, wherein
the main terminal includes a wide terminal that has one solid-state bonded portion bonded to the front surface metal body and includes an overlapping region overlapping with the front surface metal body in the thickness direction, the overlapping region including a bonded region providing the solid-state bonded portion bonded to the front surface metal body and a non-bonded region, as a region other than the bonded region in the overlapping region, being adjacent to the bonded region at least in a width direction of the main terminal, so that a width of the overlapping region is greater than a width of the solid-state bonded portion in the width direction.

2. The semiconductor device according to claim 1, further comprising:
a sealing body that seals the semiconductor element, at least a part of the substrate including the front surface metal body, the bonding material, and a part of the main terminal including the solid-state bonded portion.

3. The semiconductor device according to claim 1, wherein
the solid-state bonded portion is provided by an ultrasonic bonded portion.

4. The semiconductor device according to claim 3, wherein
the non-bonded region includes a portion that is thicker than the bonded region.

5. The semiconductor device according to claim 1, wherein
the semiconductor element and the wide terminal are aligned in a direction perpendicular to the thickness direction and the width direction.

6. The semiconductor device according to claim 5, wherein
the non-bonded region includes an end portion at an end of the wide terminal adjacent to the semiconductor element and a lateral portion on a side of the bonded region in the width direction, and
a dimension of the end portion in the direction perpendicular to the thickness direction and the width direction is smaller than a dimension of the lateral portion in the width direction.

7. The semiconductor device according to claim 1, wherein
the non-bonded region of the wide terminal and the front surface metal body provide a gap of 30 μm or less therebetween.

8. The semiconductor device according to claim 1, wherein
the non-bonded region surrounds the bonded region.

9. The semiconductor device according to claim 8, wherein
the non-bonded region entirely surrounds the bonded region.
